(19) United States
(12) Patent Application Publication
(10) Pub. No.: US 2025/0227879 A1
(43) Pub. Date: Jul. 10, 2025

(54) RACK-MOUNTED ADJUSTABLE LIQUID-COOLING MANIFOLDS

(71) Applicant: Quanta Computer Inc., Taoyuan City (TW)

(72) Inventors: Yaw-Tzorng TSORNG, Taoyuan City (TW); Ming-Lung WANG, Taoyuan City (TW); Hung-Wei CHEN, Taoyuan City (TW); Tung-Shiun YANG, Taoyuan City (TW)

(21) Appl. No.: 18/633,269

(22) Filed: Apr. 11, 2024

Related U.S. Application Data
(60) Provisional application No. 63/619,565, filed on Jan. 10, 2024.

(51) Int. Cl. H05K 7/20

(52) U.S. Cl. CPC H05K 7/20272; H05K 7/20636

(57) ABSTRACT

An adjustable, rack-mountable, liquid-cooling assembly is disclosed, enabling easy and quick mounting of a fluid manifold to a variety of mounting locations within a rack chassis. An upper mounting bracket coupled to an upper end of a rack chassis can include a plurality of upper mounting locations, and a lower mounting bracket coupled to a lower end of the rack chassis can include a plurality of corresponding lower mounting locations. An upper bracket assembly coupled to an upper end of the fluid manifold can be selectively securable to the upper mounting bracket at each of the plurality of upper mounting locations. A lower bracket coupled to a lower end of the fluid manifold can be selectively securable to the lower mounting bracket at each of the plurality of lower mounting locations.

### CROSS-REFERENCE TO RELATED APPLICATIONS

The present application claims the benefit of and priority to U.S. Provisional Application No. 63/619,565 filed Jan. 10, 2024, entitled “ADJUSTABLE BRACKETS FOR MANIFOLD ON LIQUID COOLING RACK,” the disclosure of which is hereby incorporated by reference in its entirety.

### TECHNICAL FIELD

The present disclosure relates to computing equipment generally and more specifically to cooling equipment for rack-mounted computers.

### BACKGROUND

As computer-related technologies, such as cloud computing, 5G, and artificial intelligence, continue to improve, the demand placed on the computing devices required to enable these technologies has increased. These types of computing devices generate substantial amounts of heat, especially as the technology within becomes smaller and faster. Often, computing devices are stored in computer racks. These computer racks can distribute power and network access to many computing devices (e.g., servers, storage devices, etc.) at the same time. Traditionally, the racks permit airflow that allows these computing devices to take in cooler air and expel warmer air to cool the computing devices.

More recent improvements to heat dissipation for rack-mounted computing devices have included the use of liquid cooling, in which a liquid coolant is pumped in a cycle through a heat exchanger in the computing device that permits heat to be accepted by the liquid coolant and then through a heat exchanger in a cooler environment that permits heat in the liquid coolant to be expelled into the cooler environment. While liquid cooling is a beneficial technology, management and routing of the liquid coolant can present various problems and challenges.

There is a need for improved heat dissipation solutions for rack-mounted computing devices.

### BRIEF SUMMARY

According to certain embodiments of the present disclosure, an adjustable, rack-mountable, liquid-cooling assembly comprises a fluid manifold having a supply connector and a plurality of device connectors. The liquid-cooling assembly further comprises an upper mounting bracket having a plurality of upper mounting locations. The liquid-cooling assembly further comprises a lower mounting bracket having a plurality of lower mounting locations. Each of the plurality of upper mounting locations corresponds to a respective lower mounting location of the plurality of lower mounting locations. The liquid-cooling assembly further comprises an upper bracket assembly coupled to an upper end of the fluid manifold. The upper bracket assembly is selectively securable to the upper mounting bracket at each of the plurality of upper mounting locations. The liquid-cooling assembly further comprises a lower bracket coupled to a lower end of the fluid manifold. The lower bracket is selectively securable to the lower mounting bracket at each of the plurality of lower mounting locations.

In some cases, the plurality of upper mounting locations is linearly distributed along a lateral axis, wherein the plurality of lower mounting locations is linearly distributed along an additional lateral axis that is parallel to the lateral axis. In some cases, the upper bracket assembly includes a fastener, and wherein the upper mounting bracket includes, at each of the plurality of upper mounting locations, a fastener receiver for receiving the fastener of the upper bracket assembly to removably secure the upper bracket assembly to the upper mounting bracket at the respective upper mounting location. In some cases, the upper bracket assembly includes a locator; wherein the upper mounting bracket includes, at each of the plurality of upper mounting locations, a locator receiver for receiving the locator; and wherein, at each of the plurality of upper mounting locations, the fastener of the upper bracket assembly is aligned with the respective fastener receiver when the locator engages the respective locator receiver. In some cases, the upper bracket assembly includes a slide tab; and wherein the upper mounting bracket includes a continuous slot for receiving the slide tab, the continuous slot extending for a length such that the upper bracket assembly is continuously slidable between a first upper mounting location of the plurality of upper mounting locations and a last upper mounting location of the plurality of upper mounting locations. In some cases, the upper bracket assembly includes: a vertical adjustment bracket configured to adjust the fluid manifold in a vertical direction with respect to the upper mounting bracket; and a longitudinal adjustment bracket configured to adjust the fluid manifold in a longitudinal direction with respect to the upper mounting bracket. In some cases, the vertical adjustment bracket is vertically fixed with respect to the upper mounting bracket when coupled to the upper mounting bracket at one of the plurality of upper mounting locations, the vertical adjustment bracket having a set of vertical slots for receiving a set of fasteners to couple the vertical adjustment bracket to the longitudinal adjustment bracket, coupling of the vertical adjustment bracket to the longitudinal adjustment bracket being such that vertical repositioning of the set of fasteners within the set of vertical slots results in vertical adjustment of the fluid manifold with respect to the vertical adjustment bracket. In some cases, the longitudinal adjustment bracket is coupled to and longitudinally fixed with respect to the vertical adjustment bracket, the longitudinal adjustment bracket having a longitudinal slot for receiving a manifold fastener to couple the longitudinal adjustment bracket to the fluid manifold, coupling of the longitudinal adjustment bracket to the fluid manifold being such that longitudinal repositioning of the manifold fastener within the longitudinal slot results in longitudinal adjustment of the fluid manifold with respect to the longitudinal adjustment bracket. In some cases, the vertical adjustment bracket includes a bracket window for accessing the manifold fastener when the longitudinal adjustment bracket is coupled to the vertical adjustment bracket. In some cases, the lower bracket includes at least one vertical slot for receiving at least one lower manifold fastener to couple the fluid manifold to the lower bracket such that vertical repositioning of the at least one lower manifold fastener within the at least one vertical slot results in vertical adjustment of the fluid manifold with respect to the lower bracket. In some cases, the lower bracket includes a longitudinal slot for receiving a lower fastener to couple the lower bracket to the lower mounting bracket at one of the plurality of lower mounting locations. In some cases, the upper mounting bracket and the lower mounting bracket are coupled to a rack chassis.

According to certain embodiments of the present disclosure a computer rack comprises a rack chassis having a front opening for receiving rack-mountable computing devices and a rear opening opposite the front opening. The rack chassis has a top end and a bottom end. An upper mounting bracket is coupled to the rack chassis at the top end. The upper mounting bracket has a plurality of upper mounting locations. A lower mounting bracket is coupled to the rack chassis at the bottom end. The lower mounting bracket has a plurality of lower mounting locations. Each of the plurality of upper mounting locations corresponds to a respective lower mounting location of the plurality of lower mounting locations. The computer rack further comprises a fluid manifold having a supply connector and a plurality of device connectors. The computer rack further comprises an upper bracket assembly coupled to an upper end of the fluid manifold. The upper bracket assembly is selectively securable to the upper mounting bracket at each of the plurality of upper mounting locations. The computer rack further comprises a lower bracket coupled to a lower end of the fluid manifold. The lower bracket is selectively securable to the lower mounting bracket at each of the plurality of lower mounting locations.

In some cases, the plurality of upper mounting locations is linearly distributed along a lateral axis of the rack chassis, the lateral axis being perpendicular to a vertical axis and to a longitudinal axis, the longitudinal axis being parallel to a direction of insertion of the rack-mountable computing devices, wherein the plurality of lower mounting locations is linearly distributed along an additional lateral axis that is parallel to the lateral axis. In some cases, the upper bracket assembly includes a fastener and a locator, wherein the upper mounting bracket includes, at each of the plurality of upper mounting locations, (i) a fastener receiver for receiving the fastener of the upper bracket assembly to removably secure the upper bracket assembly to the upper mounting bracket at the respective upper mounting location, and (ii) a locator receiver for receiving the locator; and wherein, at each of the plurality of upper mounting locations, the fastener of the upper bracket assembly is aligned with the respective fastener receiver when the locator engages the respective locator receiver. In some cases, the upper bracket assembly includes: a vertical adjustment bracket configured to adjust the fluid manifold in a vertical direction with respect to the upper mounting bracket; and a longitudinal adjustment bracket configured to adjust the fluid manifold in a longitudinal direction with respect to the upper mounting bracket. In some cases, the computer rack further comprises an additional upper mounting bracket coupled to the rack chassis at the top end. The additional upper mounting bracket has a plurality of additional upper mounting locations. An additional lower mounting bracket is coupled to the rack chassis at the bottom end. The additional lower mounting bracket has a plurality of additional lower mounting locations. Each of the plurality of additional upper mounting locations corresponds to a respective additional lower mounting location of the additional lower mounting bracket. An additional fluid manifold has an additional supply connector and a plurality of additional device connectors. An additional upper bracket assembly is coupled to an upper end of the additional fluid manifold. The additional upper bracket assembly is selectively securable to the additional upper mounting bracket at each of the plurality of additional upper mounting locations. An additional lower bracket is coupled to a lower end of the additional fluid manifold. The additional lower bracket is selectively securable to the additional lower mounting bracket at each of the plurality of additional lower mounting locations. A computing device is secured to the rack chassis in an installed position. The computing device has a first fluid-cooling connector and a second fluid-cooling connector. The first fluid-cooling connector is fluidly coupled to a device connector of the plurality of device connectors of the fluid manifold. The second fluid-cooling connector is fluidly coupled to an additional device connector of the plurality of additional device connectors of the additional fluid manifold.

According to certain embodiments of the present disclosure, a method comprises providing a rack chassis having a front opening for receiving rack-mountable computing devices and a rear opening opposite the front opening. The rack chassis has a top end and a bottom end. An upper mounting bracket is coupled to the rack chassis at the top end. The upper mounting bracket has a plurality of upper mounting locations. A lower mounting bracket is coupled to the rack chassis at the bottom end. The lower mounting bracket has a plurality of lower mounting locations. Each of the plurality of upper mounting locations corresponds to a respective lower mounting location of the plurality of lower mounting locations. The method further comprises providing a fluid manifold having a supply connector and a plurality of device connectors. An upper bracket assembly is coupled to an upper end of the fluid manifold. The upper bracket assembly is selectively securable to the upper mounting bracket at each of the plurality of upper mounting locations. A lower bracket is coupled to a lower end of the fluid manifold. The lower bracket is selectively securable to the lower mounting bracket at each of the plurality of lower mounting locations. The method further comprises providing a rack-mountable computing device having a set of fluid-cooling connectors. The method further comprises determining a fluid-cooling connector spacing associated with the set of fluid-cooling connectors. The method further comprises selecting a desired upper mounting location from the plurality of upper mounting locations based at least in part on the fluid-cooling connector spacing. The method further comprises securing the fluid manifold to the desired upper mounting location of the plurality of upper mounting locations. The method further comprises inserting the rack-mountable computing device into the rack chassis. Insertion of the rack-mountable computing device into the rack chassis includes fluidly coupling at least one fluid-cooling connector of the set of fluid-cooling connectors to a device connector of the plurality of device connectors of the fluid manifold.

In some cases, securing the fluid manifold to the desired upper mounting location includes adjusting a lateral position of the fluid manifold by: sliding a slide tab of the upper bracket assembly within a continuous slot of the upper mounting bracket until a locator of the upper bracket assembly engages a locator receiver of the upper mounting bracket; and securing a fastener of the upper bracket assembly to a fastener receiver of the upper mounting bracket. In some cases, the upper bracket assembly includes a vertical adjustment bracket coupled to a longitudinal adjustment bracket, the vertical adjustment bracket being coupled to the upper mounting bracket, the longitudinal adjustment bracket being coupled to the fluid manifold, wherein the method further includes: adjusting a vertical position of the fluid manifold by vertically displacing the longitudinal adjustment bracket with respect to the vertical adjustment bracket; and adjusting a longitudinal position of the fluid manifold by longitudinally displacing the fluid manifold with respect to the vertical adjustment bracket.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1 is a cutaway isometric diagram depicting a rack chassis with fluid manifolds, according to certain aspects of the present disclosure.

FIG. 2 is a partial overhead view of a rack-mountable computing device, according to certain aspects of the present disclosure.

FIG. 3 is an isometric figure depicting a rack chassis, according to certain aspects of the present disclosure.

FIG. 4 is a rear view of a rack chassis, according to certain aspects of the present disclosure.

FIG. 5 is a partial view of a top end and bottom end of a rack chassis, according to certain aspects of the present disclosure.

FIG. 6 is an exploded view of an upper end of a fluid manifold and its mounting hardware, according to certain aspects of the present disclosure.

FIG. 7 is an axonometric view of an upper mounting bracket, according to certain aspects of the present disclosure.

FIG. 8 is an axonometric view of a vertical adjustment bracket, according to certain aspects of the present disclosure.

FIG. 9 is an axonometric view of a longitudinal adjustment bracket, according to certain aspects of the present disclosure.

FIG. 10 is a partial front view of multiple potential positions for a vertical adjustment bracket, according to certain aspects of the present disclosure.

FIG. 11 is a set of views depicting a longitudinal adjustment bracket in a first longitudinal configuration and a longitudinal adjustment bracket in a second longitudinal configuration, according to certain aspects of the present disclosure.

FIG. 12 is a set of views depicting a vertical adjustment bracket in a first vertical configuration and a vertical adjustment bracket in a second vertical configuration, according to certain aspects of the present disclosure.

FIG. 13 is an exploded view depicting a lower end of a fluid manifold and its mounting hardware, according to certain aspects of the present disclosure.

FIG. 14 is an axonometric view of a lower bracket, according to certain aspects of the present disclosure.

FIG. 15 is an axonometric view of a lower mounting bracket, according to certain aspects of the present disclosure.

FIG. 16 is a set of views depicting a lower bracket in a first vertical configuration and a lower bracket in a second vertical configuration, according to certain aspects of the present disclosure.

FIG. 17 is a set of views depicting a lower bracket in a first longitudinal configuration and a lower bracket in a second longitudinal configuration, according to certain aspects of the present disclosure.

FIG. 18 is an exploded view depicting attachment of a longitudinal adjustment bracket to a fluid manifold, according to certain aspects of the present disclosure.

FIG. 19 is an exploded view depicting attachment of a vertical adjustment bracket to a longitudinal adjustment bracket, according to certain aspects of the present disclosure.

FIG. 20 is an exploded view depicting attachment of a first lower bracket to a fluid manifold, according to certain aspects of the present disclosure.

FIG. 21 is a set of partially exploded views depicting attachment of an upper mounting bracket to a rack chassis, according to certain aspects of the present disclosure.

FIG. 22 is an exploded view depicting attachment of a lower mounting bracket to a rack chassis, according to certain aspects of the present disclosure.

FIG. 23 is an isometric view depicting insertion of a fluid manifold into a rack chassis, according to certain aspects of the present disclosure.

FIG. 24 is a close up view depicting attachment of a vertical adjustment bracket to an upper mounting bracket, according to certain aspects of the present disclosure.

FIG. 25 is an exploded view depicting attachment of a lower bracket to a lower mounting bracket, according to certain aspects of the present disclosure.

### DETAILED DESCRIPTION

An adjustable, rack-mountable, liquid-cooling assembly is disclosed, enabling easy and quick mounting of a fluid manifold to a variety of mounting locations within a rack chassis. An upper mounting bracket coupled to an upper end of a rack chassis can include a plurality of upper mounting locations, and a lower mounting bracket coupled to a lower end of the rack chassis can include a plurality of corresponding lower mounting locations. An upper bracket assembly coupled to an upper end of the fluid manifold can be selectively securable to the upper mounting bracket at each of the plurality of upper mounting locations. A lower bracket coupled to a lower end of the fluid manifold can be selectively securable to the lower mounting bracket at each of the plurality of lower mounting locations.

Rack-mountable computing devices are computing devices (e.g., servers, storage devices, etc.) that are designed to be mounted in a rack chassis containing multiple rack-mountable computing devices. Liquid-cooled rack-mountable computing devices are those rack-mountable computing devices that are cooled using flowing liquid. Liquid can flow within a heat exchanger within the rack-mountable computing device to extract heat from heat-generating components within the rack-mountable computing device. Liquid is generally supplied to a rack-mountable computing device via a hose or via a blind-mate connection to a manifold.

Blind-mate types of connection methods make use of fluid-cooling connectors that seal when disconnected and open for fluid communication when connected. A pair of fluid manifolds can be mounted to a rack chassis, each of which can include numerous fluid-cooling connectors, such as a fluid-cooling connector at each rack-unit space. Coolant is circulated in one fluid manifold, through the rack-mountable computing devices, and out the other fluid manifold.

Blind-mate type connection methods provide many benefits, such as permitting a rack-mountable computing device to be installed and removed easily without the need to disconnect, reconnect, and reroute coolant hoses. Thus, setting up and maintaining such rack-mountable computing devices can be accomplished quickly and easily. However, a disadvantage to the use of blind-mate type connection methods is that the location of fluid-cooling connectors on different rack-mountable computing devices can vary, such as with different manufacturers, different purposes, different internal hardware in need of cooling, and the like. Thus, a rack chassis having a set of fluid manifolds installed therein may be limited to only being usable with a subset of rack-mountable computing devices.

As used herein, a rack chassis can have a top, a bottom, a pair of sidewalls, a front opening (e.g., an opening through which rack-mountable computing devices are inserted), and a rear opening opposite the front opening. Generally, a fluid manifold can be coupled to a rack chassis near the rear opening such that fluid-cooling connectors of a rack-mountable computing device inserted into the rack chassis through the front opening can engage the device connectors of the fluid manifold when the rack-mountable computing device is fully inserted.

According to certain aspects and features of the present disclosure, an adjustable, rack-mountable, liquid-cooling assembly can permit a fluid manifold to be secured to a number of different mounting locations within a rack chassis. Further, the fluid manifold can be adjusted to any other mounting location as needed to reconfigure the rack chassis for a different purpose. Further, the fluid manifold can be fine-tuned as necessary in vertical and longitudinal directions.

Thus, certain aspects and features of the present disclosure permit a single rack chassis to be used to provide blind-made type fluid-cooling to different rack-mountable computing devices that may have different physical specifications for the locations of their fluid-cooling connectors. By being able to adjust the position of its fluid manifolds, a single rack chassis can achieve increased compatibility, which can help reduce the design and mold costs of new development.

Certain aspects and features of the present disclosure relate to a set of brackets that are able to fix the fluid manifold in a variety of positions with respect to the rack chassis. According to certain aspects and features of the present disclosure, an upper mounting bracket and a lower mounting bracket can be secured to the rack chassis and can provide mounting locations for upper and lower bracket assemblies, respectively. Each of the mounting locations represents a different lateral position of the fluid manifold. The upper bracket assembly and lower upper bracket assembly can be secured to the upper mounting bracket and lower mounting bracket, respectively, at any of the mounting locations

Certain aspects and features of the present disclosure are described with respect to brackets mounting to other brackets or objects (e.g., a fluid manifold) via the user of fasteners and fastener receivers. As used herein, the term fastener is intended to include any suitable fastening device, such as a screw, a bolt, a rivet, a locking pin (e.g., a detent pin), or the like, as appropriate (e.g., a rivet may be appropriate to secure an upper mounting bracket to a rack chassis, but not to secure a vertical adjustment bracket to the upper mounting bracket). As used herein, the term fastener receiver is intended to include any suitable feature or component for receiving a corresponding fastener, such as a nut (e.g., a loose nut or a captive nut for receiving a bolt), an aperture (e.g., a hole for receiving a bolt or rivet), a threaded hole (e.g., for receiving a bolt), or the like.

Certain aspects and features of the present disclosure describe objects coupled together with fasteners and fastener receivers. Where appropriate, any arrangement of fasteners and fastener receivers can be modified to have a fastener be inserted in an opposite direction or to otherwise fasten in a reverse fashion. For example, instead of a longitudinal adjustment bracket having fastener receivers, the longitudinal adjustment bracket can include fasteners that extend outwards through the vertical slots of the vertical adjustment bracket and that can be secured through the use of a nut or other suitable fastener receiver.

While described with reference to fluids and the use of a fluid coolant, certain aspects and features of the present disclosure are especially useful when used with liquid coolant, such as water or another coolant that is liquid.

These illustrative examples are given to introduce the reader to the general subject matter discussed here and are not intended to limit the scope of the disclosed concepts. The following sections describe various additional features and examples with reference to the drawings in which like numerals indicate like elements, and directional descriptions are used to describe the illustrative embodiments but, like the illustrative embodiments, should not be used to limit the present disclosure. The elements included in the illustrations herein may not be drawn to scale.

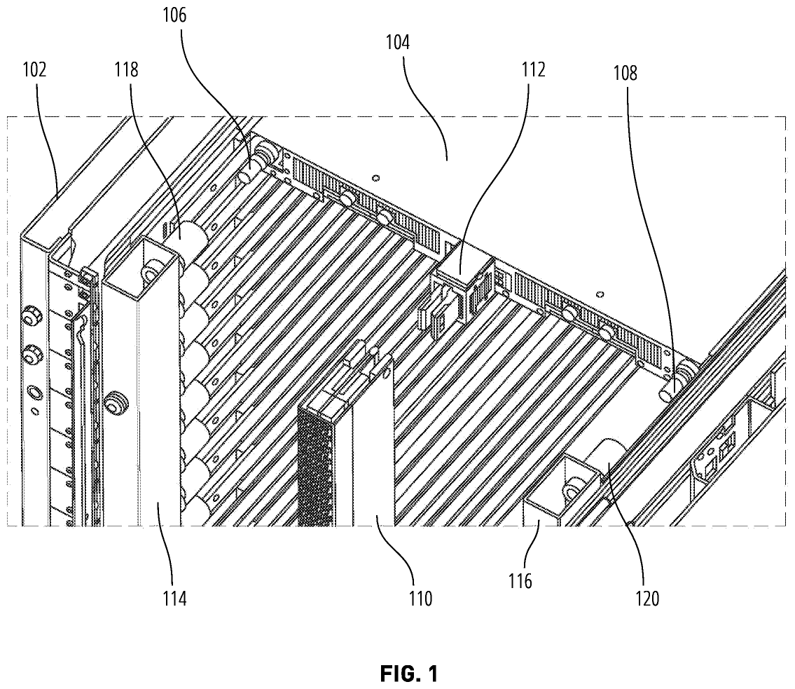

FIG. 1 is a cutaway isometric diagram depicting a rack chassis 102 with fluid manifolds 114, 116, according to certain aspects of the present disclosure. The fluid manifolds 114, 116 are mounted as described in further detail herein. Each fluid manifold 114, 116 includes a number of device connectors, such as one device connector for each rack-unit position in the rack chassis 102.

For example, a rack-mountable computing device 104 can be inserted into the rack chassis 102 in a first rack slot. The rack-mountable computing device 104 can include a first fluid-cooling connector 106 and a second fluid-cooling connector 108. Fluid entering through the first fluid-cooling connector 106 can pass through heat extraction elements within the rack-mountable computing device 104 prior to exiting through the second fluid-cooling connector 108.

Each fluid-cooling connector and device connector can be a type of blind mating connector that permits fluid communication when coupled together, but does not permit fluid communication when not coupled.

When the rack-mountable computing device 104 is fully inserted, the first fluid-cooling connector 106 will engage the first device connector 118, permitting fluid flow therebetween, and the second fluid-cooling connector 108 will engage the second device connector 120, permitting fluid flow therebetween. Cool fluid (e.g., relatively cool coolant) enters the first fluid manifold 114 and exits through each device connector to which a rack-mountable computing device 104 is coupled. Cool fluid in the first fluid manifold 114 will pass into the first fluid-cooling connector 106, through the rack-mountable computing device 104, out the second fluid-cooling connector 108, and into the second fluid manifold 116. Fluid in the second fluid manifold 116 will be pumped through a heat exchanger to allow heat collected from within the rack-mountable computing device 104 to be expelled prior to the coolant being recirculated back into the first fluid manifold 114.

In some cases, a rack-mountable computing device 104 can receive power via a power connector 112 that engages a power rail 110 of the rack chassis 102.

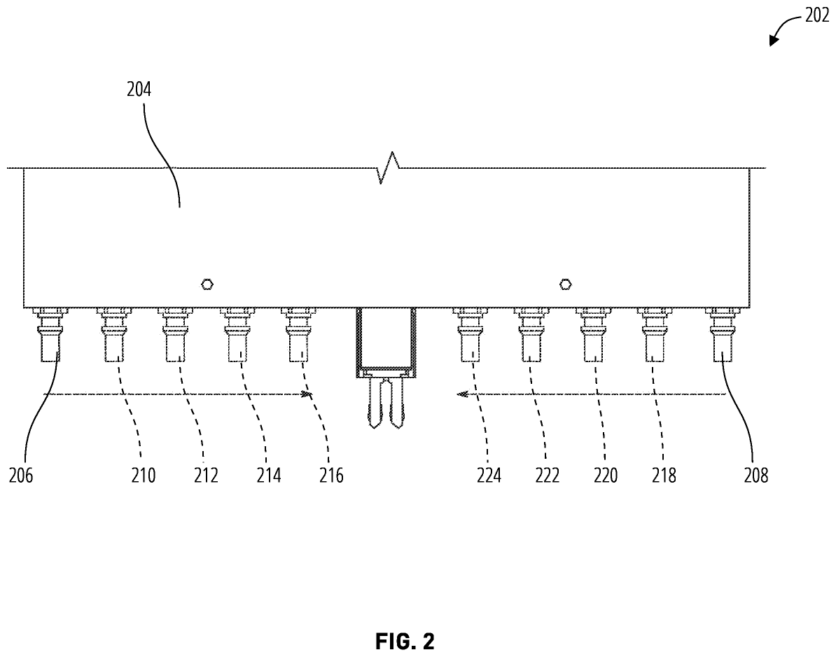

FIG. 2 is a partial overhead view of a rack-mountable computing device 202, according to certain aspects of the present disclosure. The rack-mountable computing device 202 can be any suitable rack-mountable computing device, such as rack-mountable computing device 104 of FIG. 1.

The rack-mountable computing device 202 is depicted with a first fluid-cooling connector 206 and a second fluid-cooling connector 208 as located in a first configuration. However, other configurations of the rack-mountable computing device 202 can include the first fluid-cooling connector 206 located instead at a different location, such as depicted with respect to a first alternate fluid-cooling connector A 210, a first alternate fluid-cooling connector B 212, a first alternate fluid-cooling connector C 214, or a first alternate fluid-cooling connector D 216. Likewise, in other configurations, the rack-mountable computing device 202 can include the second fluid-cooling connector 208 located instead at a different location, such as depicted with respect to second alternate fluid-cooling connector A 218, a second alternate fluid-cooling connector B 220, a second alternate fluid-cooling connector C 222, or a second alternate fluid-cooling connector D 224. Other configurations may be used.

According to certain aspects and features of the present disclosure, the ability to adjust positioning of the fluid manifolds can allow a user to easily adjust position of the fluid manifolds to match the configuration of the rack-mountable computing devices being used.

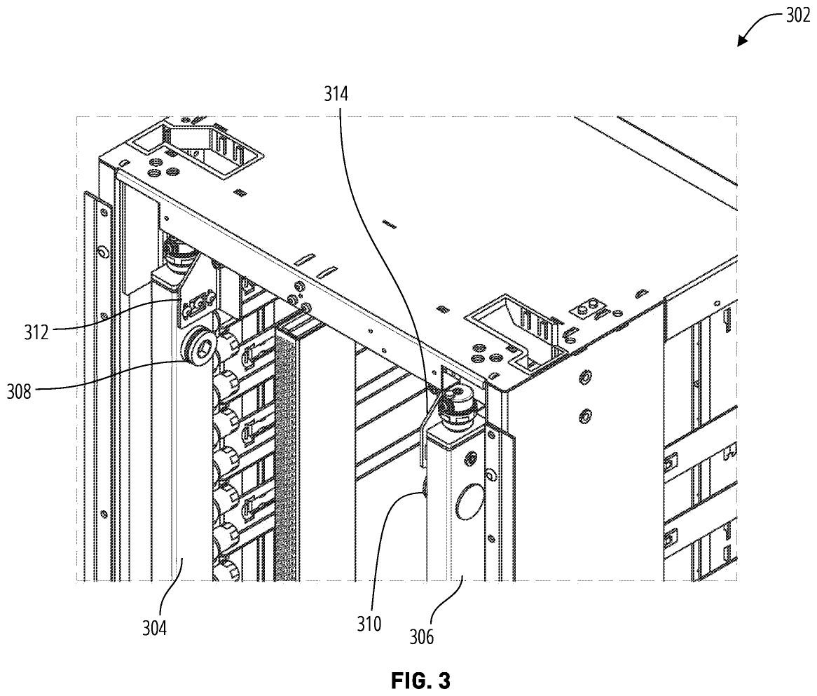

FIG. 3 is an isometric figure depicting a rack chassis 302, according to certain aspects of the present disclosure. The rack chassis 302 can be any suitable rack chassis, such as rack chassis 102 of FIG. 1. The rack chassis 302 depicted in FIG. 3 is shown with the first fluid manifold 304 and second fluid manifold 306 installed in the rack chassis 302 in a first configuration.

The rack chassis 302 includes a first fluid manifold 304 coupled to the rack chassis 302 via a first upper bracket assembly 312 and a second fluid manifold 306 coupled to the rack chassis 302 via a second upper bracket assembly 314. The first fluid manifold 304 can optionally include a first alternate manifold entrance/exit port 308 to permit an alternate location for fluid to enter or exit the first fluid manifold 304. The second fluid manifold 306 can optionally include a second alternate manifold entrance/exit port 310 to permit an alternate location for fluid to enter or exit the second fluid manifold 306.

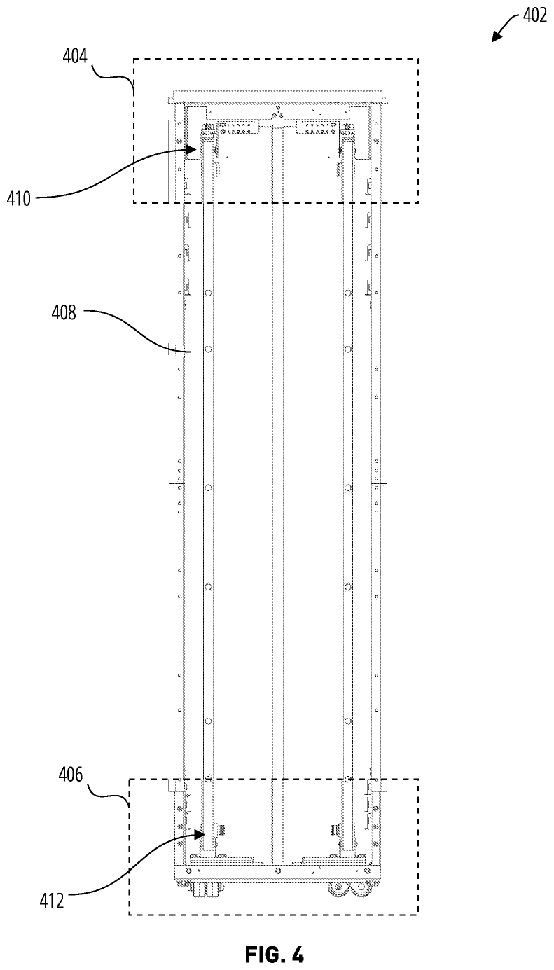

FIG. 4 is a rear view of a rack chassis 402, according to certain aspects of the present disclosure. The rack chassis 402 can be any suitable rack chassis, such as rack chassis 102 of FIG. 1. The rack chassis 102 can include a top end 404 and a bottom end 406.

Each fluid manifold 408 can include an upper end 410 coupled to the rack chassis 402 at its top end 404, and a lower end 412 coupled to the rack chassis 402 at its bottom end 406.

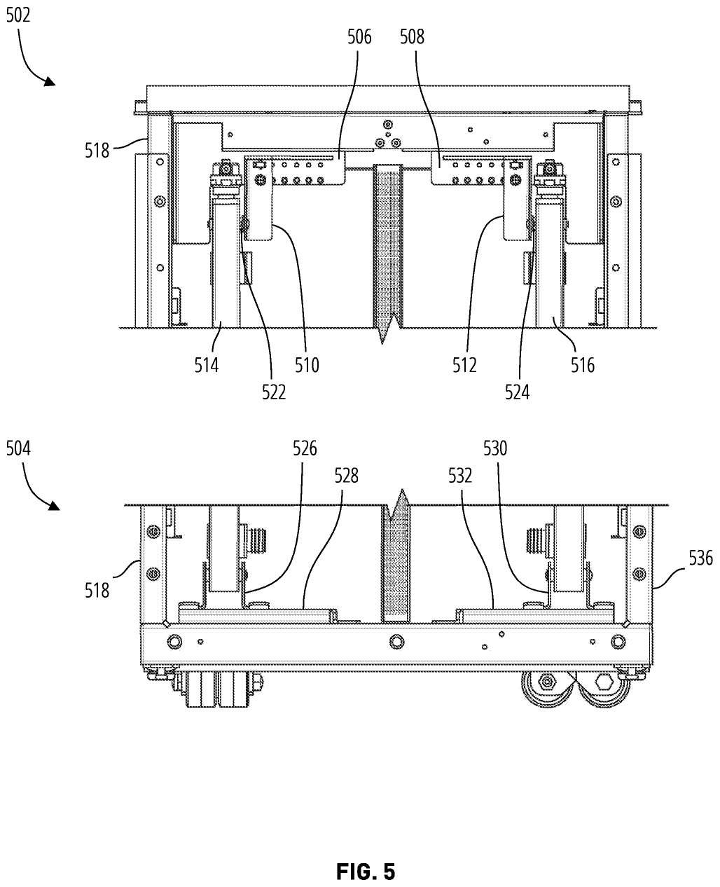

FIG. 5 is a partial view of a top end 502 and bottom end 504 of a rack chassis 518, according to certain aspects of the present disclosure. The top end 502 and bottom end 504 can be the top end 404 and bottom end 406 of the rack chassis 402 of FIG. 4.

At an upper end, the first fluid manifold 514 can be coupled to the rack chassis 518 via a first longitudinal adjustment bracket 522, a first vertical adjustment bracket 510, and a first upper mounting bracket 506. The first longitudinal adjustment bracket 522 can couple to the first fluid manifold 514 to permit adjustment in a longitudinal direction (e.g., a direction in and out of the page as depicted in FIG. 5). The first longitudinal adjustment bracket 522 can couple to the first vertical adjustment bracket 510 to permit adjustment in a vertical direction (e.g., a direction between the top and bottom of the page as depicted in FIG. 5). The first vertical adjustment bracket 510 can couple to the first upper mounting bracket 506 to permit adjustment in a longitudinal direction (e.g., a direction between the left and right of the page as depicted in FIG. 5). The first upper mounting bracket 506 can be secured to the rack chassis 518.

The second fluid manifold 516 can be coupled to the rack chassis 518 via the second longitudinal adjustment bracket 524, the second vertical adjustment bracket 512, and the second upper mounting bracket 508. In some cases, the first vertical adjustment bracket 510 and second vertical adjustment bracket 512 can be coupled to a single upper mounting bracket.

At a bottom end, the first fluid manifold 514 can be coupled to the rack chassis 518 via a first lower bracket 526 and a first lower mounting bracket 528. The first lower bracket 526 can be coupled to the first fluid manifold 514 to permit adjustment in the vertical direction. The first lower bracket 526 can be coupled to the first lower mounting bracket 528 to permit adjustment in both the longitudinal direction and the lateral direction. The first lower mounting bracket 528 can be secured to the rack chassis 518.

The second fluid manifold 516 can be coupled to the rack chassis 518 via the second lower bracket 530 and the second lower mounting bracket 532. In some cases, the first lower bracket 526 and the second lower bracket 530 can be coupled to a single lower mounting bracket.

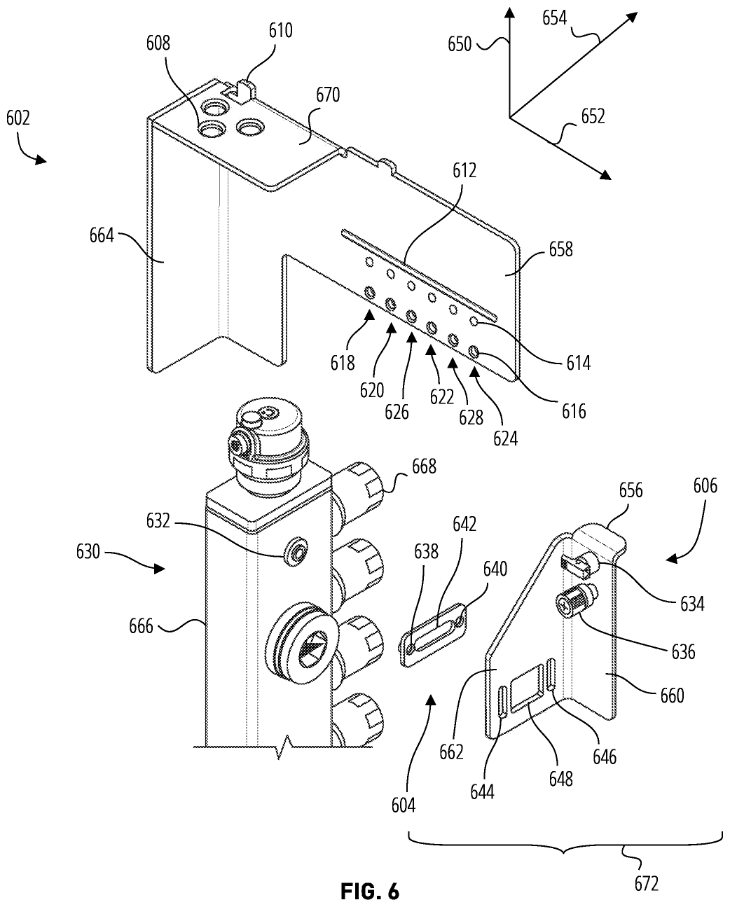

FIG. 6 is an exploded view of an upper end 630 of a fluid manifold 666 and its mounting hardware, according to certain aspects of the present disclosure. The upper end 630 of the fluid manifold 666 can include a fastener receiver 632 suitable for receiving a fastener. The fastener receiver 632 can be positioned on a face of the fluid manifold 666 that is perpendicular to a face from which the device connectors 668 protrude, such as depicted in FIG. 6, although that need not always be the case.

The upper mounting bracket 602 can include a bracket side wall 664, a bracket front wall 658, and a bracket top wall 670. The bracket top wall 670 can include fastener receivers 608 for receiving fasteners extending from the rack chassis (e.g., a bolt inserted into a hole in the rack chassis) to couple the upper mounting bracket 602 to a rack chassis (e.g., a top wall or surface of a rack chassis). In some cases, the upper mounting bracket 602 can include one or more locator tabs 610 to facilitate positioning the upper mounting bracket 602 at the correct location during installation. When coupled to the rack chassis, the bracket side wall 664 can be positioned against a sidewall of the rack chassis, with the bracket front wall 658 extending in a lateral direction 652.

The bracket front wall 658 can include a continuous slot 612, a set of locator receivers 614, and a set of fastener receivers 616 (e.g., threaded holes). The locator receiver locator receivers 614 and fastener receivers 616 can be arranged in a set of pre-determined mounting locations (e.g., first location 618, second location 620, third location 626, fourth location 622, fifth location 628, and sixth location 624). One fastener receiver 616 and one locator receiver 614 can be associated with each pre-determined mounting location. The set of pre-determined mounting locations can extend linearly in a lateral direction 652, thus offering multiple locations for mounting the fluid manifold 666.

An upper bracket assembly 672 can be used to couple the fluid manifold 666 to the upper mounting bracket 602. The upper bracket assembly 672 can include a vertical adjustment bracket 606 and a longitudinal adjustment bracket 604.

The vertical adjustment bracket 606 can include a bracket front wall 660 and a bracket side wall 662. When the vertical adjustment bracket 606 is installed, the bracket front wall 660 can be parallel to the bracket front wall 658 and the bracket side wall 662 can be perpendicular to the bracket front wall 660. The vertical adjustment bracket 606 can include a slide tab 656 that fits within the continuous slot 612 to permit the vertical adjustment bracket 606 to slide between the various pre-determined mounting locations. The slide tab 656 can engage a bottom surface of the continuous slot 612 to help keep the vertical adjustment bracket 606 from falling while adjusting its mounting location.

The continuous slot 612 can extend at least from a first region associated with the first location 618 to a second region associated with the last location (e.g., sixth location 624). In some cases, the first region of the continuous slot 612 is located vertically offset from the first location 618, although that need not always be the case. For example, if the slide tab 656 of the vertical adjustment bracket 606 is laterally offset from the locator 634 by a given distance, the first region of the continuous slot 612 may be laterally offset from the first location 618 by the same distance. As depicted herein, however, the slide tab 656 is in vertical alignment with the locator 634.

The vertical adjustment bracket 606 can include a locator 634 that engages a locator receiver 614 as the vertical adjustment bracket 606 slides into the pre-determined mounting location associated with that locator receiver 614. The locator 634 and locator receivers 614 can form detent mechanisms for slowing or stopping sliding movement of the vertical adjustment bracket 606 along the continuous slot 612 whenever the vertical adjustment bracket 606 is in a pre-determined mounting location. Any suitable locator 634 and corresponding locator receiver 614 can be used. As depicted in FIG. 6, the locator 634 is a spring-loaded plunger that is biased in a longitudinal direction 654 such that the plunger will naturally fall into a locator receiver 614 when it is positioned over the locator receiver 614, but can be manually pulled out of the locator receiver 614 to permit further movement of the vertical adjustment bracket 606.

A fastener 636 can be used to secure the vertical adjustment bracket 606 to the upper mounting bracket 602 at any of the pre-determined mounting locations by engaging the corresponding fastener receiver 616 for a pre-determined mounting location. The locator 634 and locator receivers 614 are arranged such that when the locator 634 engages the locator receiver 614 for a particular pre-determined mounting location, the fastener 636 will be aligned over the corresponding fastener receiver 616. As depicted in FIG. 6, the fastener 636 is a captive screw that can be received by a fastener receiver 616 that is a threaded hole.

Thus, different positioning of the fluid manifold 666 along the lateral direction 652 can be accomplished by securing the vertical adjustment bracket 606 to the upper mounting bracket 602 at the different pre-determined mounting locations. While upper mounting bracket 602 is depicted as having six pre-determined mounting locations, in some cases it can have more or fewer. While upper mounting bracket 602 is shown as extending in a lateral direction 652 for a limited extent, in some cases the upper mounting bracket 602 can extend from one sidewall of the rack chassis to the opposite sidewall, with pre-determined mounting locations along the full length, thus allowing multiple fluid manifolds 666 to be mounted to the same upper mounting bracket 602 at different pre-determined mounting locations.

The vertical adjustment bracket 606 can include a left vertical slot 644 and a right vertical slot 646 into which fasteners can be inserted to coupled to the left fastener receiver 638 and right fastener receiver 640, respectively, of the longitudinal adjustment bracket 604. Because the left vertical slot 644 and right vertical slot 646 are vertically extending slots, the fasteners used in the slots can be moved in a vertical direction from a lower end to an upper end, thus permitting the longitudinal adjustment bracket 604 to be coupled to the vertical adjustment bracket 606 at various vertical positions. The fasteners need only be loosed to reposition the longitudinal adjustment bracket 604 with respect to the vertical adjustment bracket 606, at which time the fasteners can be tightened to retain the longitudinal adjustment bracket 604 at the new vertical position.

The longitudinal adjustment bracket 604 can include a longitudinal slot 642 into which a fastener can be inserted to engage a fastener receiver 632 in the fluid manifold 666, thus coupling the fluid manifold 666 to the longitudinal adjustment bracket 604. Because the longitudinal slot 642 is a longitudinally extending slot that extends from a first end to a second end, the fastener within can be slid along the length of the longitudinal slot 642 to longitudinally reposition the fluid manifold 666 with respect to the longitudinal adjustment bracket 604.

The vertical adjustment bracket 606 can include a bracket window 648, such as between the left vertical slot 644 and the right vertical slot 646. The bracket window 648 can be sufficiently large to permit access to a fastener within the longitudinal slot 642. Thus, the fastener that couples the longitudinal adjustment bracket 604 to the fluid manifold 666 can be adjusted, permitting adjustment of the longitudinal position of the fluid manifold 666 with respect to the rack chassis, without needing to remove the longitudinal adjustment bracket 604 from the vertical adjustment bracket 606.

Generally, at least two fluid manifolds 666 are used with a single rack chassis: one for providing cooler coolant to the rack-mountable computing devices and one for receiving heated coolant from the rack-mountable computing devices. In some cases, a single upper mounting bracket 602 can be used to mount multiple fluid manifolds 666, although that need not always be the case. As depicted, each fluid manifold 666 is mounted with a respective upper mounting bracket 602. The upper mounting bracket 602 depicted in FIG. 6 can be used on a first side of the rack chassis, whereas a mirrored version of the upper mounting bracket 602 can be used on the opposite side of the rack chassis. In some cases, the same vertical adjustment bracket 606 can be used for the fluid manifolds on either side of the rack chassis, although in some cases a mirrored version of the vertical adjustment bracket 606 can be used.

In some cases, each of the upper mounting bracket 602, the longitudinal adjustment bracket 604, and the vertical adjustment bracket 606 can be made of a respective single piece of metal, such as a single piece of stamped and folded steel.

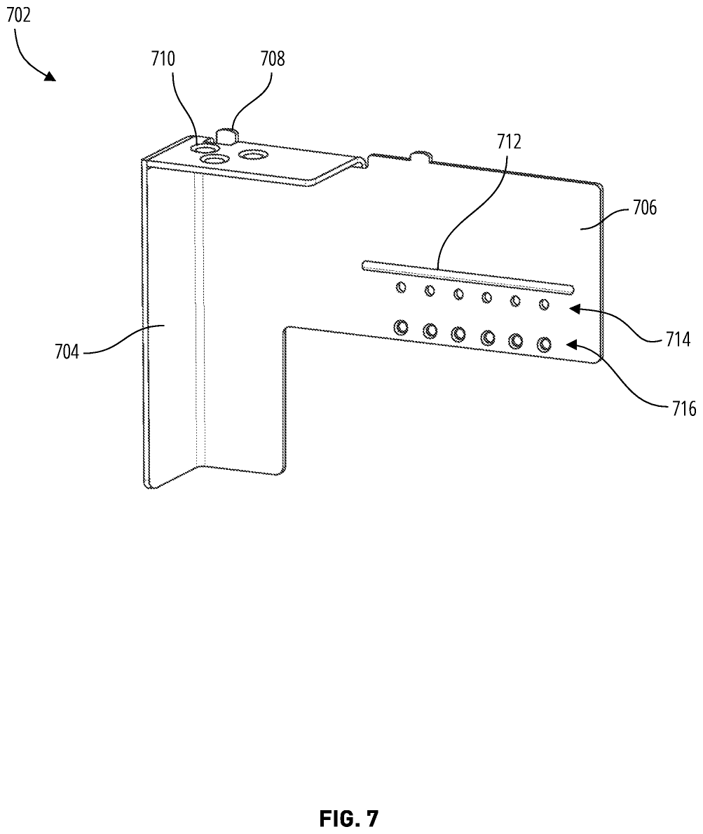

FIG. 7 is an axonometric view of an upper mounting bracket 702, according to certain aspects of the present disclosure. The upper mounting bracket 702 can be upper mounting bracket 602 of FIG. 6. As seen in FIG. 7, the upper mounting bracket 702 includes a front wall 706 and a side wall 704. The side wall 704 can abut a sidewall of a rack chassis when the upper mounting bracket 702 is installed. The front wall 706 can include a continuous slot 712 and a set of locator receivers 714 and fastener receivers 716, one of each for each of a plurality of pre-determined mounting locations. The upper mounting bracket 702 can mount to a top of a rack chassis via mounting apertures 710 (e.g., via inserting a bolt into each mounting aperture 710 and into the rack chassis). A locator tab 708 may be included to help align the upper mounting bracket 702 to the proper location within a rack chassis. In some cases, upper mounting bracket 702 can be made of a single piece of metal, such as a single piece of stamped and folded steel.

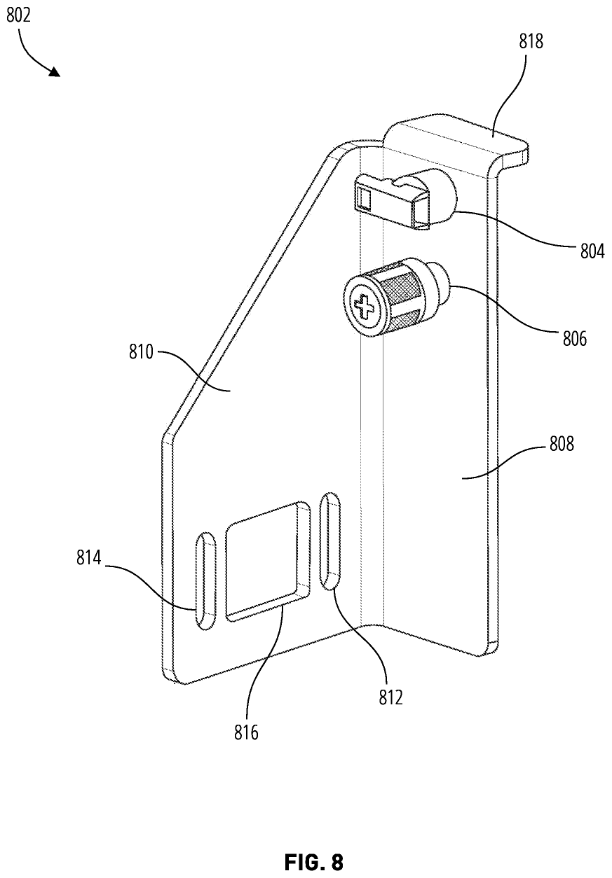

FIG. 8 is an axonometric view of a vertical adjustment bracket 802, according to certain aspects of the present disclosure. The vertical adjustment bracket 802 can be vertical adjustment bracket 606 of FIG. 6. As seen in FIG. 8, the vertical adjustment bracket 802 can include a bracket front wall 808 and a bracket side wall 810. The bracket front wall 808 can include a fastener 806 (e.g., or an opening for receiving a fastener 806), a locator 804, and a slide tab 818. The bracket side wall 810 can include a left vertical slot 814, a right vertical slot 812, and a bracket window 816.

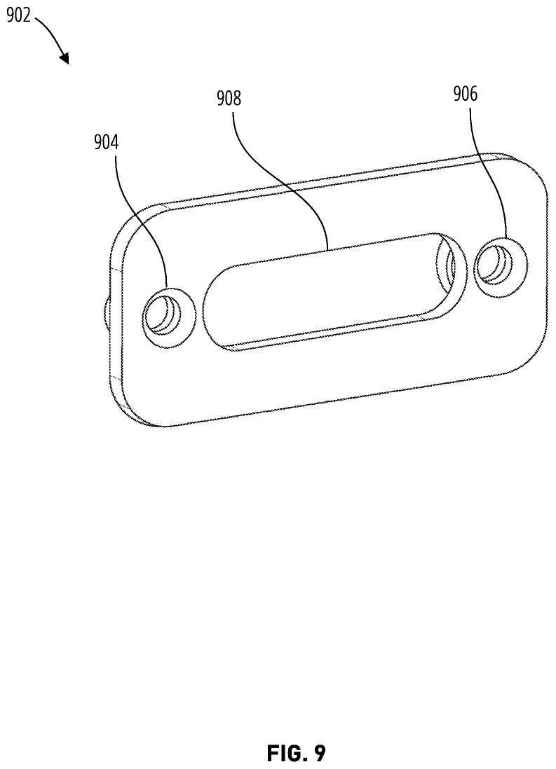

FIG. 9 is an axonometric view of a longitudinal adjustment bracket 902, according to certain aspects of the present disclosure. The longitudinal adjustment bracket 902 can be the longitudinal adjustment bracket 604 of FIG. 6. As seen in FIG. 9, the longitudinal adjustment bracket 902 can include a left fastener receiver 904 and right fastener receiver 906 for receiving fasteners to couple the longitudinal adjustment bracket 902 to a vertical adjustment bracket. The longitudinal adjustment bracket 902 can further include a longitudinal slot 908 into which a fastener can be inserted to secure the longitudinal adjustment bracket 902 to a fluid manifold.

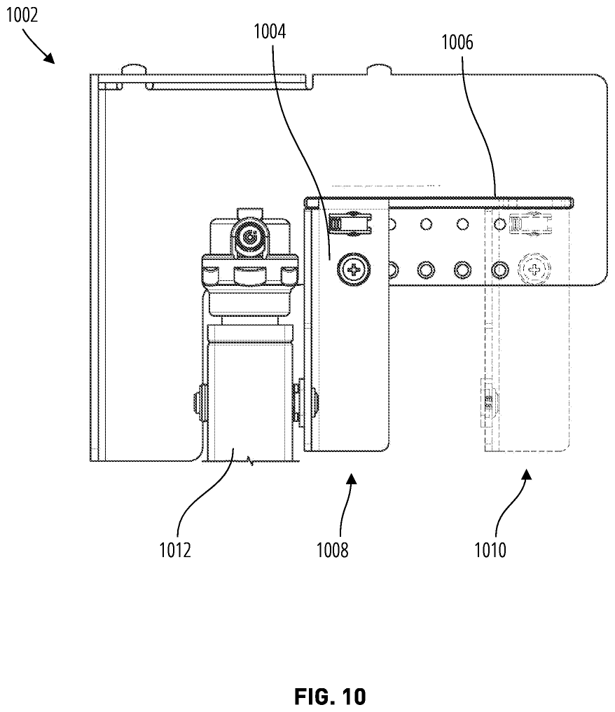

FIG. 10 is a partial front view of multiple potential positions for a vertical adjustment bracket 1004, according to certain aspects of the present disclosure. The upper mounting bracket 1002 and vertical adjustment bracket 1004 can be upper mounting bracket 602 and vertical adjustment bracket 606 of FIG. 6.

The solid lines in FIG. 10 depict vertical adjustment bracket 1004 located in an initial location 1008. In this initial location 1008, the vertical adjustment bracket 1004 holds the fluid manifold 1012 as seen (e.g., towards the left of FIG. 10). The dashed lines in FIG. 10 depict an alternate location 1010 for the vertical adjustment bracket 1004 if the vertical adjustment bracket 1004 had been slid laterally along continuous slot 1006 towards the right as seen in FIG. 6. The initial location 1008 and alternate location 1010 can correspond to the first location 618 and the sixth location 624 of FIG. 6, respectively.

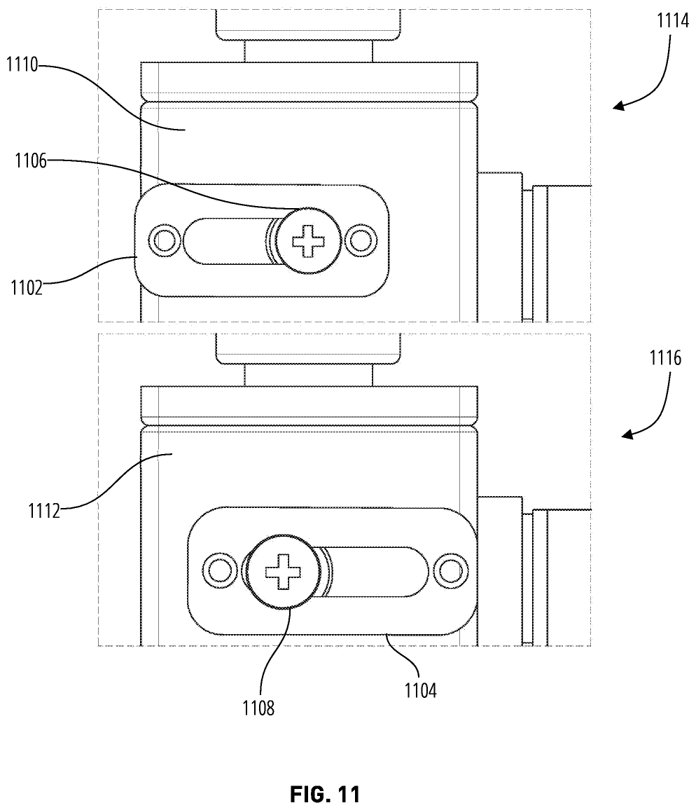

FIG. 11 is a set of views depicting a longitudinal adjustment bracket 1102 in a first longitudinal configuration 1114 and a longitudinal adjustment bracket 1104 in a second longitudinal configuration 1116, according to certain aspects of the present disclosure. The longitudinal adjustment bracket 1102 and longitudinal adjustment bracket 1104 can be longitudinal adjustment bracket 604 of FIG. 6, in two different longitudinal configurations.

In the first longitudinal configuration 1114, the fluid manifold 1110 is positioned towards a most-forward longitudinal position with respect to the longitudinal adjustment bracket 1102. In the first longitudinal configuration 1114, the fastener 1106 is positioned towards the most-forward end of the longitudinal slot of the longitudinal adjustment bracket 1102.

In the second longitudinal configuration 1116, the fluid manifold 1112 is positioned towards a most-rearward longitudinal position with respect to the longitudinal adjustment bracket 1102. In the second longitudinal configuration 1116, the fastener 1108 is positioned towards the most-rearward end of the longitudinal slot of the longitudinal adjustment bracket 1104.

As used herein, a fastener (e.g., fastener 1106 or fastener 1108) used to couple a longitudinal adjustment bracket (e.g., longitudinal adjustment bracket 1102 or longitudinal adjustment bracket 1104) to a fluid manifold (e.g., fluid manifold 1110 or fluid manifold 1112) can be referred to as a manifold fastener.

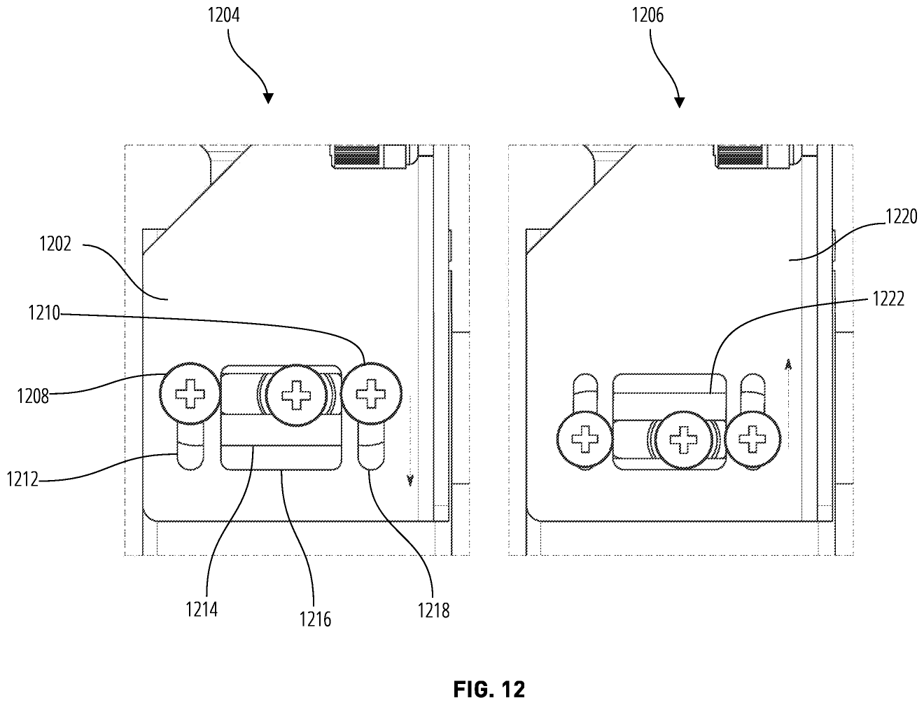

FIG. 12 is a set of views depicting a vertical adjustment bracket 1202 in a first vertical configuration 1204 and a vertical adjustment bracket 1220 in a second vertical configuration 1206, according to certain aspects of the present disclosure. The vertical adjustment bracket 1202 and vertical adjustment bracket 1220 can be the vertical adjustment bracket 606 of FIG. 6, in two different vertical configurations.

The longitudinal adjustment bracket 1214 is coupled to the vertical adjustment bracket 1202 via left fastener 1208 and right fastener 1210. When the left fastener 1208 and right fastener 1210 are pushed to the top of the left vertical slot 1212 and the right vertical slot 1218, respectively, the longitudinal adjustment bracket 1214 will be in a highest vertical position (e.g., the first vertical configuration 1204). However, in the second vertical configuration 1206, the longitudinal adjustment bracket 1222 is moved to a lowest vertical position with respect to the 1220.

The fastener used for longitudinal adjustment is accessible through the bracket window 1216.

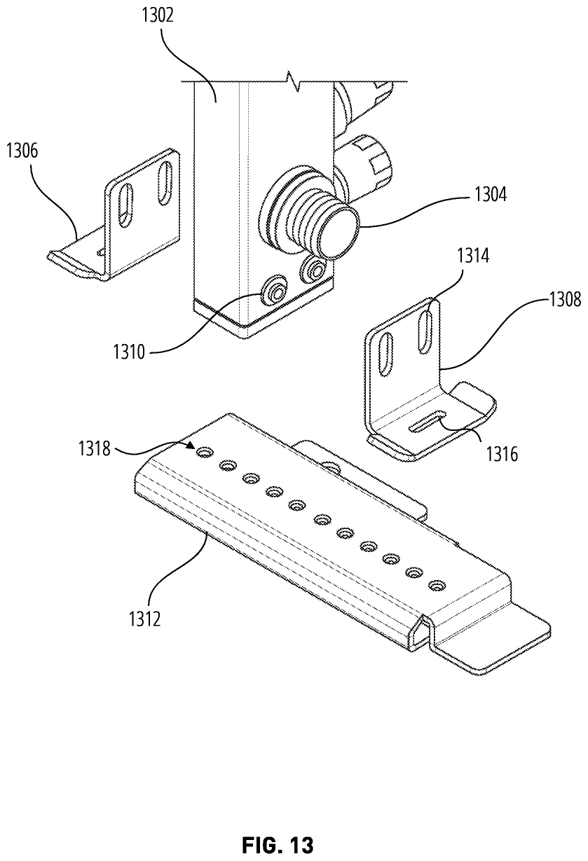

FIG. 13 is an exploded view depicting a lower end of a fluid manifold 1302 and its mounting hardware, according to certain aspects of the present disclosure. The lower mounting bracket 1312 can be the first lower mounting bracket 528 of FIG. 5.

The fluid manifold 1302 can include a number of fastener receivers 1310 to which fasteners can be attached to help secure the lower end of the fluid manifold 1302. As seen in FIG. 13, the fluid manifold 1302 includes four fastener receivers 1310 (e.g., two on each side). A left lower bracket 1306 and a right lower bracket 1308 can include vertical slots 1314 that correspond to each of the fastener receivers 1310 of the fluid manifold 1302. The left lower bracket 1306 and the right lower bracket 1308 can include lower slots 1316 into which fasteners can be inserted to couple each of the left lower bracket 1306 and the right lower bracket 1308 to the lower mounting bracket 1312.

The lower mounting bracket 1312 can include a number of fastener receivers 1318 corresponding to respective mounting locations of an upper mounting bracket (e.g., mounting locations 618, 620, 622, 624, 626, 628 of FIG. 6). In some cases, two lower brackets (e.g., left lower bracket 1306 and right lower bracket 1308) are used to secure a lower end of the fluid manifold 1302, whereas only a single bracket (e.g., upper bracket assembly 672 of FIG. 6) is used to secure an upper end of the fluid manifold 1302. In such cases, each mounting location at the upper mounting bracket would be associated with as few as one fastener receiver, however each corresponding mounting location at the lower mounting bracket 1312 would be associated with two fastener receivers 1310 (e.g., one for the left lower bracket 1306 and one for the right lower bracket 1308 when the fluid manifold 1302 is at the mounting location).

In some cases, each of the left lower bracket 1306, right lower bracket 1308, and lower mounting bracket 1312 can be made of a respective single piece of metal, such as a single piece of stamped and folded steel.

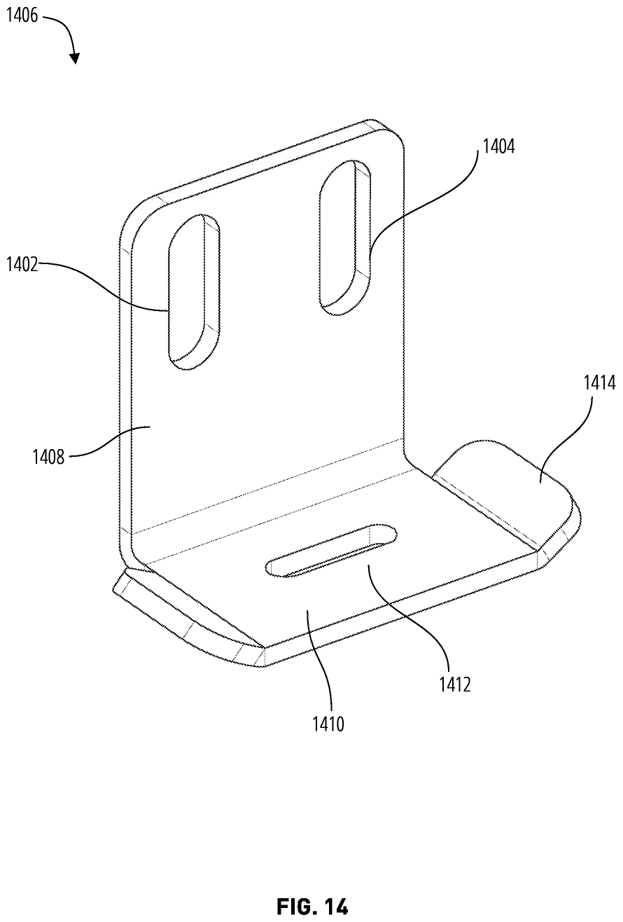

FIG. 14 is an axonometric view of a lower bracket 1406, according to certain aspects of the present disclosure. The lower bracket 1406 can be right lower bracket 1308 of FIG. 13. The lower bracket 1406 can include a side wall 1408 and a lower wall 1410. The side wall 1408 can abut a fluid manifold when the lower bracket 1406 is coupled to a fluid manifold. The lower wall 1410 can abut a lower mounting bracket when the lower bracket 1406 is coupled to a lower mounting bracket.

The side wall 1408 can include a left vertical slot 1402 and right vertical slot 1404, into which respective fasteners can be inserted to couple the lower bracket 1406 to a fluid manifold.

Because the left vertical slot 1402 and right vertical slot 1404 are vertical slots that extend for a length in the vertical direction, the vertical position of the fluid manifold with respect to the lower bracket 1406 can be adjusted by adjusting the vertical position of the fasteners within the left vertical slot 1402 and right vertical slot 1404.

The lower bracket 1406 can include wings 1414, such as wings 1414 formed as extensions from the lower wall 1410, which can be used to facilitate sliding the lower wall 1410 along a lower mounting bracket. The lower wall 1410 can include a lower slot 1412 into which a fastener can be inserted to secure the lower bracket 1406 to a lower mounting bracket. The lower slot 1412 can extend for a length in a longitudinal direction. Because the lower slot 1412 is a slot extending in a longitudinal direction, the longitudinal position of the fluid manifold with respect to the lower bracket 1406 can be adjusted by adjusting the longitudinal position of the fasteners within the lower slot 1412.

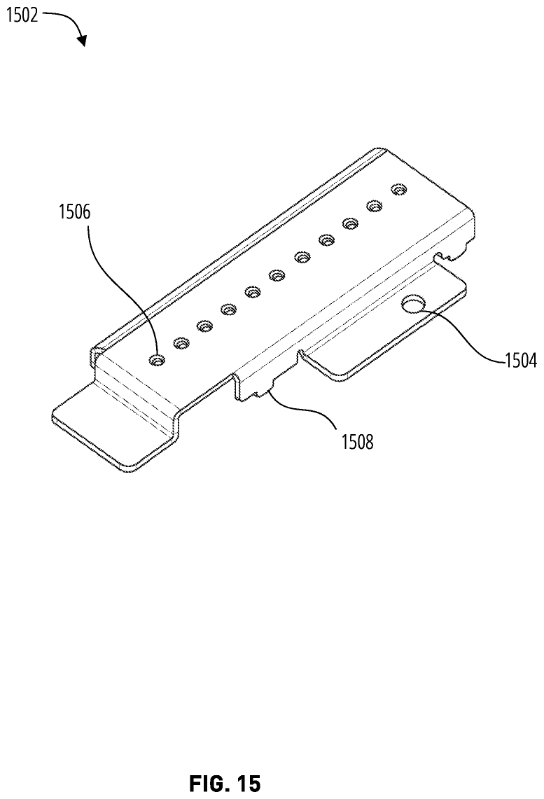

FIG. 15 is an axonometric view of a lower mounting bracket 1502, according to certain aspects of the present disclosure. The lower mounting bracket 1502 can be lower mounting bracket 1312 of FIG. 13. The lower mounting bracket 1502 can include a number of fastener receivers 1506. The lower mounting bracket 1502 can be secured to a bottom surface of a rack chassis via a fastener inserted into a mounting aperture 1504, although in some cases additional mounting apertures can be used. In some cases, the lower mounting bracket 1502 can include one or more locator tabs 1508, which can facilitate aligning the lower mounting bracket 1312 into a proper position with respect to the rack chassis.

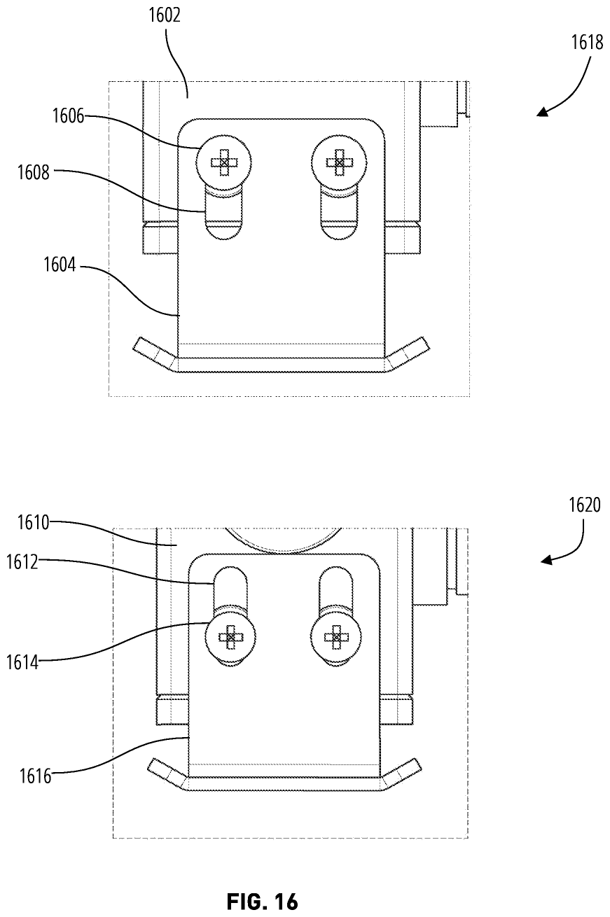

FIG. 16 is a set of views depicting a lower bracket 1604 in a first vertical configuration 1618 and a lower bracket 1616 in a second vertical configuration 1620, according to certain aspects of the present disclosure. The lower bracket 1604 can be right lower bracket 1308 of FIG. 13.

In a first vertical configuration 1618, the lower bracket 1604 can be coupled to the fluid manifold 1602 via fasteners 1606 inserted into vertical slots 1608. In the first vertical configuration 1618, the fastener fasteners 1606 are in a highest vertical position within the vertical slots 1608, thus positioning the fluid manifold 1602 at a highest vertical position with respect to the lower bracket 1604.

In a second vertical configuration 1620, the fasteners 1614 are in a lowest vertical position within the vertical slots 1612, thus positioning the fluid manifold 1610 at a lowest vertical position with respect to the lower bracket 1604.

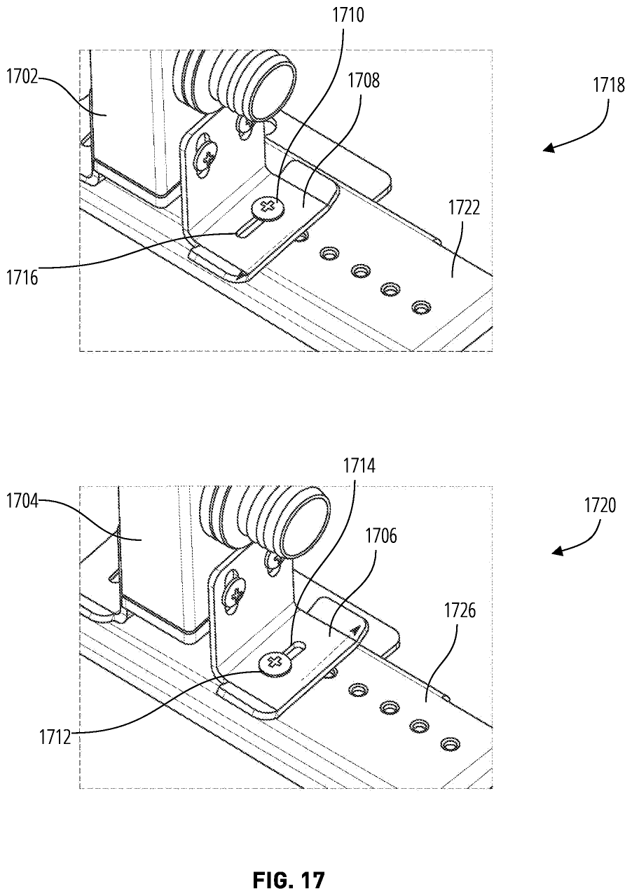

FIG. 17 is a set of views depicting a lower bracket 1708 in a first longitudinal configuration 1718 and a lower bracket 1706 in a second longitudinal configuration 1720, according to certain aspects of the present disclosure. The lower bracket 1708 can be right lower bracket 1308 of FIG. 13.

In the first longitudinal configuration 1718, the fastener 1710 securing the lower bracket 1708 to the lower mounting bracket 1722 is at a forwardmost longitudinal position within the lower slot 1716, which positions the fluid manifold 1702 at a forwardmost longitudinal position with respect to the lower mounting bracket 1722.

In the second longitudinal configuration 1720, the fastener 1712 is at a rearmost longitudinal position within the lower slot 1714, which positions the fluid manifold 1704 at a rearmost longitudinal position with respect to the lower mounting bracket 1726.

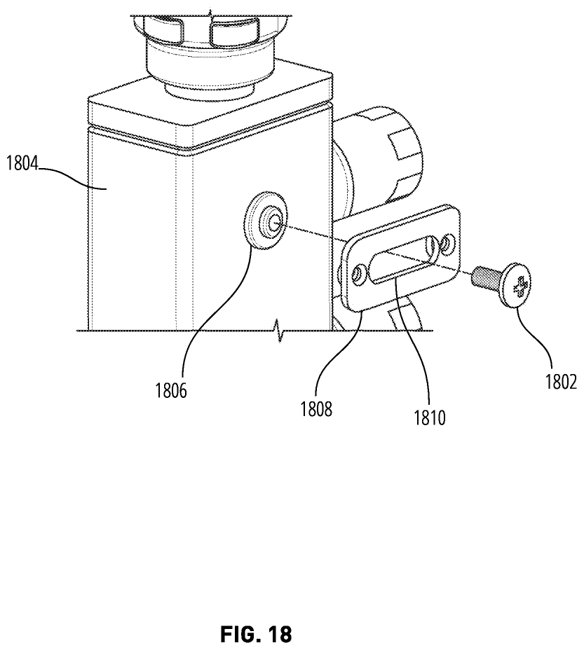

FIG. 18 is an exploded view depicting attachment of a longitudinal adjustment bracket 1808 to a fluid manifold 1804, according to certain aspects of the present disclosure. The fluid manifold 1804 and longitudinal adjustment bracket 1808 can be fluid manifold 666 and longitudinal adjustment bracket 604 of FIG. 6, respectively.

The longitudinal adjustment bracket 1808 can be coupled to the fluid manifold 1804 via a fastener 1802 being inserted into longitudinal slot 1810 and engaging fastener receiver 1806. For example, a bolt can be inserted into the longitudinal slot 1810 and into a fastener receiver 1806 that is a captive bolt or a threaded hole. Once the fastener 1802 is tightened, the fluid manifold 1804 will be securely coupled to the longitudinal adjustment bracket 1808. If desired, loosening of the fastener 1802 (e.g., removal of the fastener 1802 or loosening without full removal) can permit the fluid manifold 1804 to move in a longitudinal direction according to the longitudinal slot 1810.

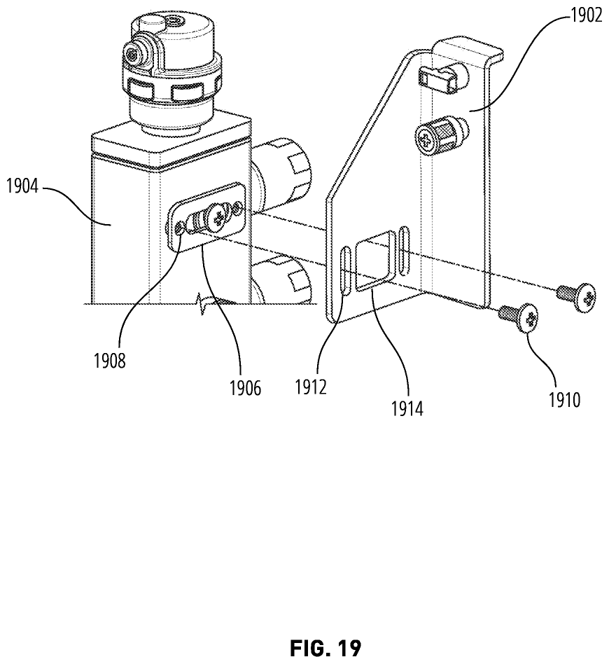

FIG. 19 is an exploded view depicting attachment of a vertical adjustment bracket 1902 to a longitudinal adjustment bracket 1906, according to certain aspects of the present disclosure. The vertical adjustment bracket 1902 can be vertical adjustment bracket 606 of FIG. 6.

The vertical adjustment bracket 1902 is coupled to the longitudinal adjustment bracket 1906 via a pair of fasteners 1910 that are inserted into a pair of vertical slots 1912 in the vertical adjustment bracket 1902 and are received by a pair of fastener receivers 1908 of the longitudinal adjustment bracket 1906. The longitudinal adjustment bracket 1906 can be coupled to a fluid manifold 1904. Once the fasteners 1910 are tightened, the longitudinal adjustment bracket 1906 (and thus any connected fluid manifold 1904) will be securely coupled to the vertical adjustment bracket 1902. If desired, loosening of the fasteners 1910 (e.g., removal of the fasteners 1910 or loosening without full removal) can permit the fluid manifold 1904 to move in a vertical direction according to the vertical slots 1912.

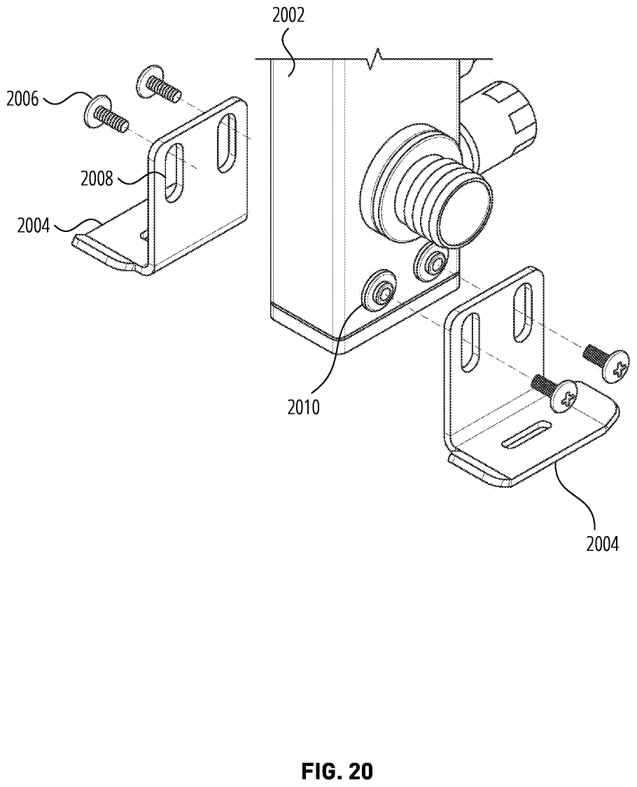

FIG. 20 is an exploded view depicting attachment of a pair of lower brackets 2004 to a fluid manifold 2002, according to certain aspects of the present disclosure. The lower brackets 2004 can be the first lower bracket 526 and second lower bracket 530 of FIG. 5.

Each lower bracket 2004 can be coupled to the fluid manifold 2002 via a pair of fasteners 2006 that are inserted into a pair of vertical slots 2008 in the lower bracket 2004 and are received by a pair of fastener receivers 2010 of the fluid manifold 2002. Once the fasteners 2006 are tightened, the fluid manifold 2002 will be securely coupled to the lower bracket 2004. If desired, loosening of the fasteners 2006 (e.g., removal of the fasteners 2006 or loosening without full removal) can permit the fluid manifold 2002 to move in a vertical direction according to the vertical slots 2008.

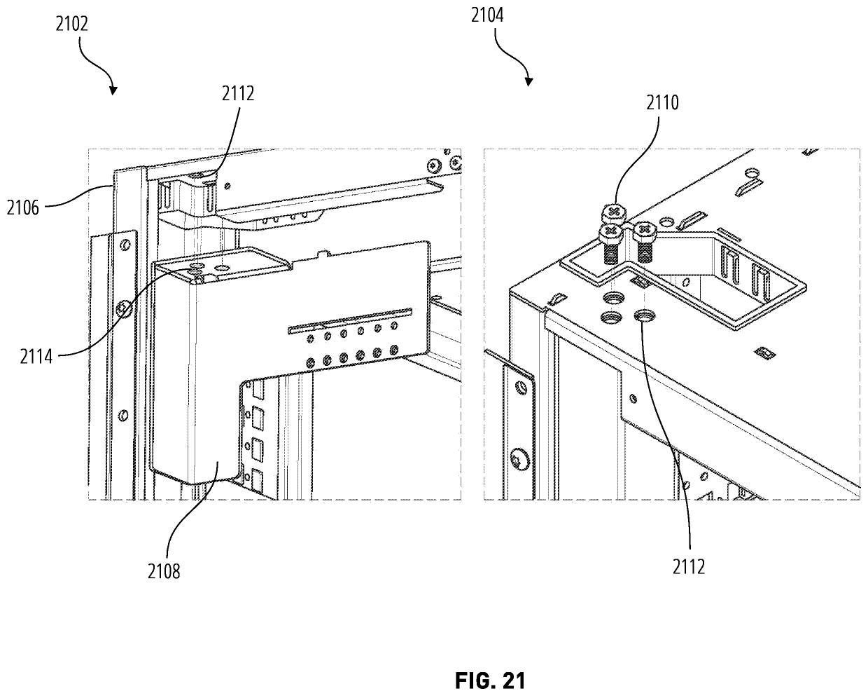

FIG. 21 is a set of partially exploded views depicting attachment of an upper mounting bracket 2108 to a rack chassis 2106, according to certain aspects of the present disclosure. The upper mounting bracket 2108 and rack chassis 2106 can be first upper mounting bracket 506 and rack chassis 518 of FIG. 5.

In the lower view 2102, the underside of the upper mounting bracket 2108 is seen, with the fastener receivers 2114 (e.g., threaded holes) aligned to corresponding mounting apertures 2112 of the rack chassis 2106. In the upper view 2104, a set of fasteners 2110 (e.g., bolts) are shown aligned with the mounting apertures 2112. The upper mounting bracket 2108 can be coupled to the rack chassis 2106 by passing the fasteners 2110 through the mounting apertures 2112 and screwing them into the fastener receivers 2114 until tightened.

In some cases, the fastener receivers 2114 can be replaced with mounting apertures and nuts or other fastener receivers could be used to engage the fasteners 2110 after they have passed through the mounting apertures 2112 and the mounting apertures of the upper mounting bracket 2108.

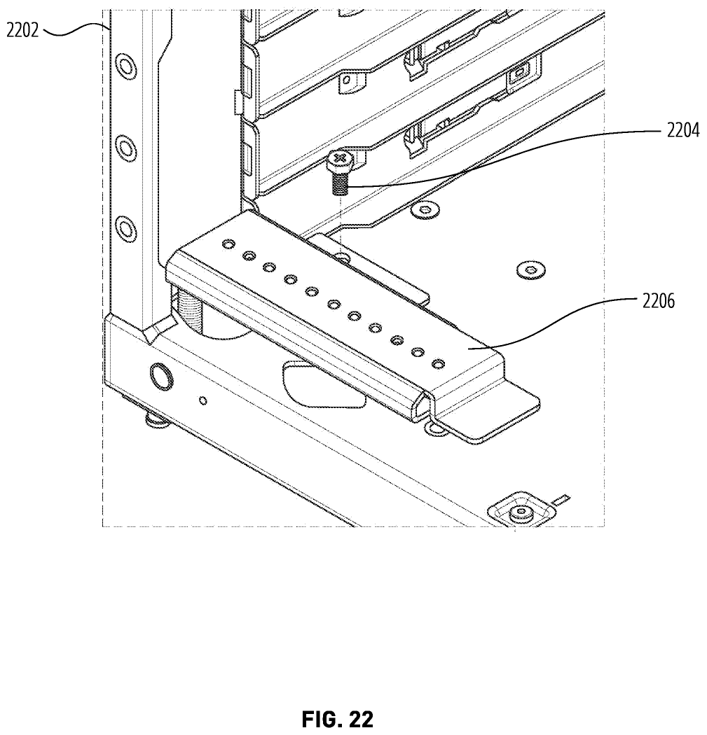

FIG. 22 is an exploded view depicting attachment of a lower mounting bracket 2206 to a rack chassis 2202, according to certain aspects of the present disclosure. The lower mounting bracket 2206 could be first lower mounting bracket 528 of FIG. 5. The lower mounting bracket 2206 can be secured to the rack chassis 2202 (e.g., on a floor of the rack chassis 2202) via a fastener 2204 (e.g., a bolt). In some cases, features (e.g., tabs, walls, etc.) of the lower mounting bracket 2206 can contact corresponding portions of the rack chassis 2202 to prevent movement of the lower mounting bracket 2206 in certain directions (e.g., in a longitudinal or lateral direction). In such cases, the fastener 2204 can facilitate securing the lower mounting bracket 2206 to the rack chassis 2202 without necessarily bearing all the longitudinal or lateral force exerted upon the lower mounting bracket 2206.

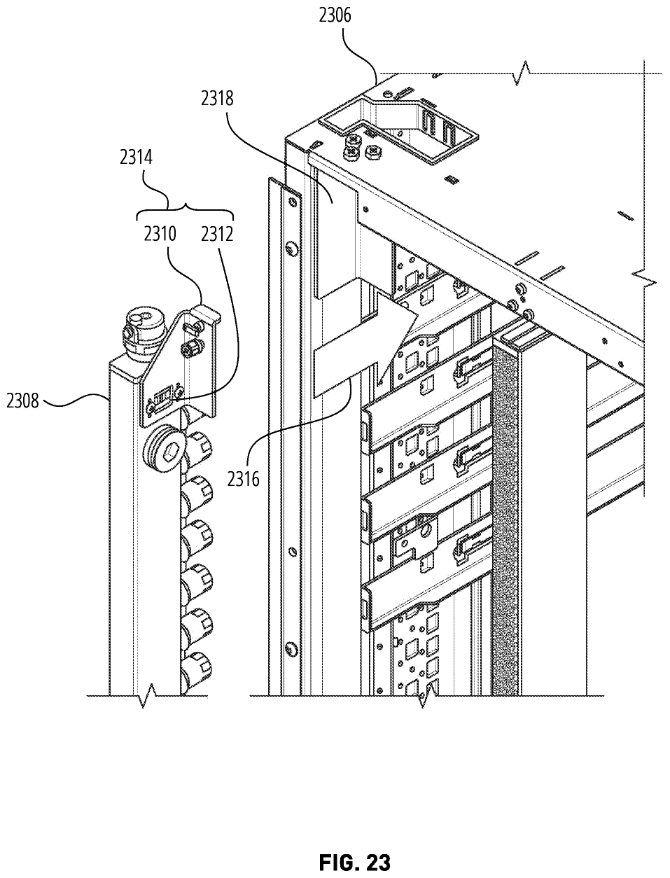

FIG. 23 is an isometric view depicting insertion of a fluid manifold 2308 into a rack chassis 2306, according to certain aspects of the present disclosure. The fluid manifold 2308 and rack chassis 2306 can be first fluid manifold 514 and rack chassis 518 of FIG. 5.

The fluid manifold 2308 is shown with an attached upper bracket assembly 2314, which includes a vertical adjustment bracket 2310 coupled to a longitudinal adjustment bracket 2312, which is coupled to the fluid manifold 2308. When inserted in a longitudinal direction, as depicted by arrow 2316, the vertical adjustment bracket 2310 can engage the upper mounting bracket 2318 (e.g., a slide tab of the vertical adjustment bracket 2310 can fit into a continuous slot of the upper mounting bracket 2318).

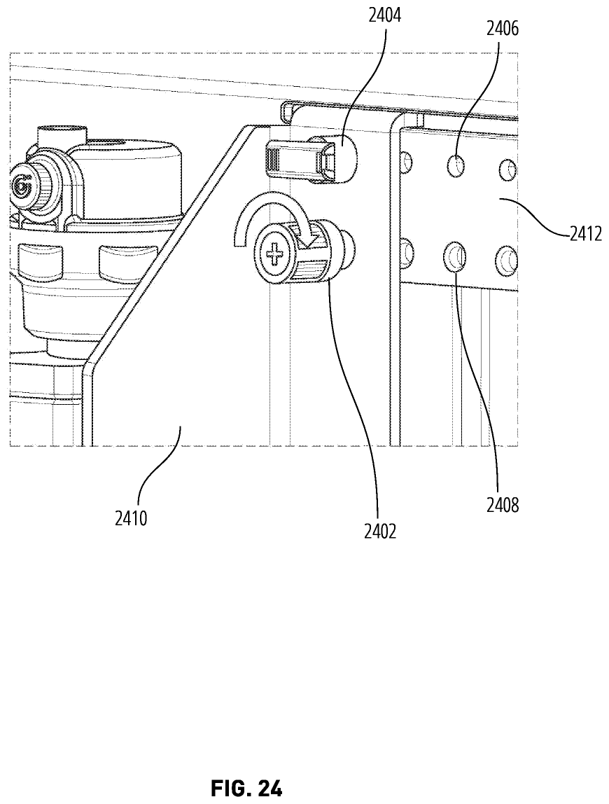

FIG. 24 is a close up view depicting attachment of a vertical adjustment bracket 2410 to an upper mounting bracket 2412, according to certain aspects of the present disclosure. The vertical adjustment bracket 2410 and upper mounting bracket 2412 can be vertical adjustment bracket 2310 and upper mounting bracket 2318 of FIG. 23. As depicted in FIG. 24, a slide tab of the vertical adjustment bracket 2410 is inserted into a continuous slot of the upper mounting bracket 2412, which would allow the vertical adjustment bracket 2410 to slide to multiple mounting locations. When at a mounting location, a locator 2404 of the vertical adjustment bracket 2410 can automatically engage a locator receiver 2406 of the upper mounting bracket 2412 to stop the vertical adjustment bracket 2410 at the mounting location. The vertical adjustment bracket 2410 can be moved to another mounting location by disengaging the locator 2404 (e.g., pulling on a spring-biased plunger) from the locator receiver 2406 and continuing to slide the vertical adjustment bracket 2410. When at a desired mounting location, the fastener 2402 (e.g., bolt) of the vertical adjustment bracket 2410 can engage the fastener receiver 2408 (e.g., threaded hole) of the upper mounting bracket 2412 to secure the vertical adjustment bracket 2410 in place at that mounting location.

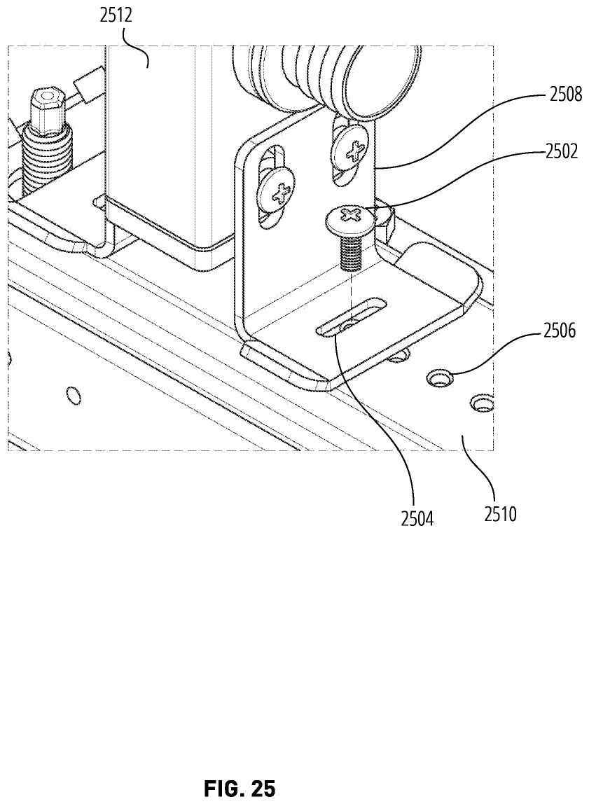

FIG. 25 is an exploded view depicting attachment of a lower bracket 2508 to a lower mounting bracket 2510, according to certain aspects of the present disclosure. The lower bracket 2508 and lower mounting bracket 2510 can be first lower bracket 526 and first lower mounting bracket 528 of FIG. 5. The act of mounting the lower bracket 2508 to the lower mounting bracket 2510 can occur after the upper bracket assembly is mounted to the upper mounting bracket, although that need not always be the case.

The lower bracket 2508 is shown already coupled to a fluid manifold 2512. When the fluid manifold 2512 is in the desired mounting position, a fastener 2502 can be passed through the lower slot 2504 of the lower bracket 2508 to engage a corresponding fastener receiver 2506 of the lower mounting bracket 2510. When tightened, the fastener 2502 secures the lower bracket 2508, and thus the fluid manifold 2512 in place. Longitudinal adjustment of the lower end of the fluid manifold 2512 can be accomplished by moving the lower bracket 2508 longitudinally while the fastener 2502 is loose or removed, then once the correct longitudinal position is achieved, tightening the fastener 2502 into the fastener receiver 2506.

The foregoing description of the embodiments, including illustrated embodiments, has been presented only for the purpose of illustration and description and is not intended to be exhaustive or limiting to the precise forms disclosed. Numerous modifications, adaptations, and uses thereof will be apparent to those skilled in the art. Numerous changes to the disclosed embodiments can be made in accordance with the disclosure herein, without departing from the spirit or scope of the disclosure. Thus, the breadth and scope of the present disclosure should not be limited by any of the above described embodiments.

Although certain aspects and features of the present disclosure have been illustrated and described with respect to one or more implementations, equivalent alterations and modifications will occur or be known to others skilled in the art upon the reading and understanding of this specification and the annexed drawings. In addition, while a particular feature may have been disclosed with respect to only one of several implementations, such feature may be combined with one or more other features of the other implementations as may be desired and advantageous for any given or particular application.

The terminology used herein is for the purpose of describing particular embodiments only, and is not intended to be limiting of the disclosure. As used herein, the singular forms “a,” “an,” and “the” are intended to include the plural forms as well, unless the context clearly indicates otherwise. Furthermore, to the extent that the terms “including,” “includes,” “having,” “has,” “with,” or variants thereof, are used in either the detailed description and/or the claims, such terms are intended to be inclusive in a manner similar to the term “comprising.”

One or more elements or aspects or steps, or any portion(s) thereof, from one or more of any of the claims below can be combined with one or more elements or aspects or steps, or any portion(s) thereof, from one or more of any of the other claims below or combinations thereof, to form one or more additional implementations and/or claims of the present disclosure.

What is claimed is:

1. An adjustable, rack-mountable, liquid-cooling assembly, the liquid-cooling assembly comprising:
a fluid manifold having a supply connector and a plurality of device connectors;
an upper mounting bracket having a plurality of upper mounting locations;
a lower mounting bracket having a plurality of lower mounting locations, each of the plurality of upper mounting locations corresponding to a respective lower mounting location of the plurality of lower mounting locations;
an upper bracket assembly coupled to an upper end of the fluid manifold, the upper bracket assembly being selectively securable to the upper mounting bracket at each of the plurality of upper mounting locations; and
a lower bracket coupled to a lower end of the fluid manifold, the lower bracket selectively securable to the lower mounting bracket at each of the plurality of lower mounting locations.

2. The liquid-cooling assembly of claim 1, wherein the plurality of upper mounting locations is linearly distributed along a lateral axis, the plurality of lower mounting locations being linearly distributed along an additional lateral axis that is parallel to the lateral axis.

3. The liquid-cooling assembly of claim 1, wherein the upper bracket assembly includes a fastener, and wherein the upper mounting bracket includes, at each of the plurality of upper mounting locations, a fastener receiver for receiving the fastener of the upper bracket assembly to removably secure the upper bracket assembly to the upper mounting bracket at the respective upper mounting location.

4. The liquid-cooling assembly of claim 3,
wherein the upper bracket assembly includes a locator;
wherein the upper mounting bracket includes, at each of the plurality of upper mounting locations, a locator receiver for receiving the locator; and
wherein, at each of the plurality of upper mounting locations, the fastener of the upper bracket assembly is aligned with the respective fastener receiver when the locator engages the respective locator receiver.

5. The liquid-cooling assembly of claim 1,
wherein the upper bracket assembly includes a slide tab; and
wherein the upper mounting bracket includes a continuous slot for receiving the slide tab, the continuous slot extending for a length such that the upper bracket assembly is continuously slidable between a first upper mounting location of the plurality of upper mounting locations and a last upper mounting location of the plurality of upper mounting locations.

6. The liquid-cooling assembly of claim 1, wherein the upper bracket assembly includes:
a vertical adjustment bracket configured to adjust the fluid manifold in a vertical direction with respect to the upper mounting bracket; and
a longitudinal adjustment bracket configured to adjust the fluid manifold in a longitudinal direction with respect to the upper mounting bracket.

7. The liquid-cooling assembly of claim 6, wherein the vertical adjustment bracket is vertically fixed with respect to the upper mounting bracket when coupled to the upper mounting bracket at one of the plurality of upper mounting locations, the vertical adjustment bracket having a set of vertical slots for receiving a set of fasteners to couple the vertical adjustment bracket to the longitudinal adjustment bracket, the coupling of the vertical adjustment bracket to the longitudinal adjustment bracket being such that vertical repositioning of the set of fasteners within the set of vertical slots results in vertical adjustment of the fluid manifold with respect to the vertical adjustment bracket.

8. The liquid-cooling assembly of claim 6, wherein the longitudinal adjustment bracket is coupled to and longitudinally fixed with respect to the vertical adjustment bracket, the longitudinal adjustment bracket having a longitudinal slot for receiving a manifold fastener to couple the longitudinal adjustment bracket to the fluid manifold, the coupling of the longitudinal adjustment bracket to the fluid manifold being such that longitudinal repositioning of the manifold fastener within the longitudinal slot results in longitudinal adjustment of the fluid manifold with respect to the longitudinal adjustment bracket.

9. The liquid-cooling assembly of claim 8, wherein the vertical adjustment bracket includes a bracket window for accessing the manifold fastener when the longitudinal adjustment bracket is coupled to the vertical adjustment bracket.

10. The liquid-cooling assembly of claim 1, wherein the lower bracket includes at least one vertical slot for receiving at least one lower manifold fastener to couple the fluid manifold to the lower bracket such that vertical repositioning of the at least one lower manifold fastener within the at least one vertical slot results in vertical adjustment of the fluid manifold with respect to the lower bracket.

11. The liquid-cooling assembly of claim 10, wherein the lower bracket includes a longitudinal slot for receiving a lower fastener to couple the lower bracket to the lower mounting bracket at one of the plurality of lower mounting locations.

12. The liquid-cooling assembly of claim 1, wherein the upper mounting bracket and the lower mounting bracket are coupled to a rack chassis.

13. A computer rack, comprising:
a rack chassis having a front opening for receiving rack-mountable computing devices and a rear opening opposite the front opening, the rack chassis having a top end and a bottom end;
an upper mounting bracket coupled to the rack chassis at the top end, the upper mounting bracket having a plurality of upper mounting locations;
a lower mounting bracket coupled to the rack chassis at the bottom end, the lower mounting bracket having a plurality of lower mounting locations, each of the plurality of upper mounting locations corresponding to a respective lower mounting location of the plurality of lower mounting locations;
a fluid manifold having a supply connector and a plurality of device connectors;
an upper bracket assembly coupled to an upper end of the fluid manifold, the upper bracket assembly being selectively securable to the upper mounting bracket at each of the plurality of upper mounting locations; and
a lower bracket coupled to a lower end of the fluid manifold, the lower bracket selectively securable to the lower mounting bracket at each of the plurality of lower mounting locations.

14. The computer rack of claim 13, wherein the plurality of upper mounting locations is linearly distributed along a lateral axis of the rack chassis, the lateral axis being perpendicular to a vertical axis and to a longitudinal axis, the longitudinal axis being parallel to a direction of insertion of the rack-mountable computing devices, the plurality of lower mounting locations being linearly distributed along an additional lateral axis that is parallel to the lateral axis.

15. The computer rack of claim 13,
wherein the upper bracket assembly includes a fastener and a locator,
wherein the upper mounting bracket includes, at each of the plurality of upper mounting locations, (i) a fastener receiver for receiving the fastener of the upper bracket assembly to removably secure the upper bracket assembly to the upper mounting bracket at the respective upper mounting location, and (ii) a locator receiver for receiving the locator; and
wherein, at each of the plurality of upper mounting locations, the fastener of the upper bracket assembly is aligned with the respective fastener receiver when the locator engages the respective locator receiver.

16. The computer rack of claim 13, wherein the upper bracket assembly includes:
a vertical adjustment bracket configured to adjust the fluid manifold in a vertical direction with respect to the upper mounting bracket; and
a longitudinal adjustment bracket configured to adjust the fluid manifold in a longitudinal direction with respect to the upper mounting bracket.

17. The computer rack of claim 16, further comprising:
an additional upper mounting bracket coupled to the rack chassis at the top end, the additional upper mounting bracket having a plurality of additional upper mounting locations;
an additional lower mounting bracket coupled to the rack chassis at the bottom end, the additional lower mounting bracket having a plurality of additional lower mounting locations, each of the plurality of additional upper mounting locations corresponding to a respective additional lower mounting location of the additional lower mounting bracket;
an additional fluid manifold having an additional supply connector and a plurality of additional device connectors;
an additional upper bracket assembly coupled to an upper end of the additional fluid manifold, the additional upper bracket assembly being selectively securable to the additional upper mounting bracket at each of the plurality of additional upper mounting locations;
an additional lower bracket coupled to a lower end of the additional fluid manifold, the additional lower bracket selectively securable to the additional lower mounting bracket at each of the plurality of additional lower mounting locations; and
a computing device secured to the rack chassis in an installed position, the computing device having a first fluid-cooling connector and a second fluid-cooling connector, the first fluid-cooling connector being fluidly coupled to a device connector of the plurality of device connectors of the fluid manifold, the second fluid-cooling connector being fluidly coupled to an additional device connector of the plurality of additional device connectors of the additional fluid manifold.

18. A method, comprising:
providing a rack chassis having a front opening for receiving rack-mountable computing devices and a rear opening opposite the front opening, the rack chassis having a top end and a bottom end, an upper mounting bracket coupled to the rack chassis at the top end, the upper mounting bracket having a plurality of upper mounting locations, a lower mounting bracket coupled to the rack chassis at the bottom end, the lower mounting bracket having a plurality of lower mounting locations, each of the plurality of upper mounting locations corresponding to a respective lower mounting location of the plurality of lower mounting locations;
providing a fluid manifold having a supply connector and a plurality of device connectors, an upper bracket assembly coupled to an upper end of the fluid manifold, the upper bracket assembly being selectively securable to the upper mounting bracket at each of the plurality of upper mounting locations, a lower bracket coupled to a lower end of the fluid manifold, the lower bracket selectively securable to the lower mounting bracket at each of the plurality of lower mounting locations;
providing a rack-mountable computing device having a set of fluid-cooling connectors;
determining a fluid-cooling connector spacing associated with the set of fluid-cooling connectors;
selecting a desired upper mounting location from the plurality of upper mounting locations based at least in part on the fluid-cooling connector spacing;
securing the fluid manifold to the desired upper mounting location of the plurality of upper mounting locations; and
inserting the rack-mountable computing device into the rack chassis, wherein insertion of the rack-mountable computing device into the rack chassis includes fluidly coupling at least one fluid-cooling connector of the set of fluid-cooling connectors to a device connector of the plurality of device connectors of the fluid manifold.

19. The method of claim 18, wherein securing the fluid manifold to the desired upper mounting location includes adjusting a lateral position of the fluid manifold by:
sliding a slide tab of the upper bracket assembly within a continuous slot of the upper mounting bracket until a locator of the upper bracket assembly engages a locator receiver of the upper mounting bracket; and
securing a fastener of the upper bracket assembly to a fastener receiver of the upper mounting bracket.

20. The method of claim 18, wherein the upper bracket assembly includes a vertical adjustment bracket coupled to a longitudinal adjustment bracket, the vertical adjustment bracket being coupled to the upper mounting bracket, the longitudinal adjustment bracket being coupled to the fluid manifold, wherein the method further includes:
adjusting a vertical position of the fluid manifold by vertically displacing the longitudinal adjustment bracket with respect to the vertical adjustment bracket; and
adjusting a longitudinal position of the fluid manifold by longitudinally displacing the fluid manifold with respect to the vertical adjustment bracket.
